(19) United States
(12) Patent Application Publication
(10) Pub. No.: US 2026/0013333 A1
(43) Pub. Date: Jan. 8, 2026

(54) DISPLAY PANEL AND ELECTRONIC DEVICE INCLUDING THE SAME

(71) Applicant: Samsung Display Co., Ltd., Yongin-Si (KR)

(72) Inventors: YOOMIN KO, Yongin-si (KR); SUNHO KIM, Yongin-si (KR); JUCHAN PARK, Yongin-si (KR); Yerim SON, Yongin-si (KR); CHUNG SOCK CHOI, Yongin-si (KR)

(21) Appl. No.: 19/257,457

(22) Filed: Jul. 1, 2025

(30) Foreign Application Priority Data
Jul. 3, 2024 (KR) 10-2024-0087389

(51) Int. Cl. H10K 59/122

(52) U.S. Cl. CPC H10K 59/122

(57) ABSTRACT

Provided is a display panel including a driving element layer, a light-emitting element including a first electrode, an intermediate layer, and a second electrode, a pixel defining film having an opening, a separator disposed on the pixel defining film and surrounding at least a portion of the opening, and a plurality of spacers disposed on the separator and spaced apart from each other, wherein the separator includes a first portion having a first taper angle and a second portion having a second taper angle, wherein the width of the first portion may be greater than the width of the second portion, and the first portion is between the plurality of spacers and the second portion.

### CROSS-REFERENCE TO RELATED APPLICATIONS

This U.S. non-provisional patent application claims priority, under 35 U.S.C. § 119, to Korean Patent Application No. 10-2024-0087389 filed on Jul. 3, 2024, the entire content of which is hereby incorporated by reference.

### BACKGROUND

The present disclosure herein relates to a display panel and an electronic device with improved product reliability.

Multimedia electronic devices such as televisions, mobile phones, tablets, computers, navigation systems, game consoles, etc. are provided with a display panel for displaying an image. The display panel includes a light-emitting element and a circuit for driving the light-emitting element. The light-emitting elements included in the display panel emit light and create an image according to a voltage applied from the circuit. Research on the connection of a light-emitting element and a circuit is being conducted in order to improve the reliability of the display panel.

### SUMMARY

The present disclosure provides a display panel and an electronic device with improved manufacturing yield and product reliability from reduced defects.

An embodiment of the inventive concept provides a display panel including a driving element layer including a pixel driver, a light-emitting element disposed on the driving element layer and including a first electrode, an intermediate layer disposed on the first electrode, and a second electrode disposed on the intermediate layer, a pixel defining film disposed on the driving element layer and having an opening that exposes at least a portion of the first electrode, a separator disposed on the pixel defining film and surrounding at least a portion of the opening, and a plurality of spacers disposed on the separator and spaced apart from each other, wherein the separator includes a first portion including a first side surface having a first taper angle and a second portion including a second side surface having a second taper angle different from the first taper angle, wherein the first portion may be wider than the second portion, and the first portion is between the plurality of spacers and the second portion.

In an embodiment, the separator may include a line extending along a first direction, and the plurality of spacers may be spaced apart from each other along the first direction.

In an embodiment, when viewed on a plane, the separator may include a plurality of first lines extending in a first direction and a plurality of second lines extending in a second direction that crosses the first direction.

In an embodiment, the separator may further include a plurality of cross-intersection regions where the plurality of first lines and the plurality of second lines intersect.

In an embodiment, the plurality of spacers may be disposed to correspond one-to-one with at least some of the plurality of cross-intersection regions.

In an embodiment, the plurality of spacers may include a spacer having a cross shape, and the spacer may be disposed in one of the plurality of cross-intersection regions.

In an embodiment, the separator may further include a plurality of T-shaped intersection regions in which the plurality of first lines and the plurality of second lines meet.

In an embodiment, the plurality of spacers may include a spacer having a T shape, and the spacer may be disposed in one of the plurality of T-shaped intersection regions.

In an embodiment, the plurality of spacers may include a spacer having a shape in which a width in the first direction is greater than a length in the second direction, and the spacer may overlap one of the plurality of first lines.

In an embodiment, the plurality of spacers may include a spacer having at least one of a circular, tetragonal, triangular, and irregular shape.

In an embodiment, the light-emitting element may be provided as a plurality of light-emitting elements, a plurality of light-emitting portions may be defined in the plurality of light-emitting elements, the plurality of light-emitting portions may be divided into a plurality of groups having a same arrangement, and a first proportion of an area occupied by the separator out of an area of a unit region may be greater than a second proportion an area occupied by the plurality of spacers out of an area of the unit region.

In an embodiment, a plurality of intermediate layers and a plurality of second electrodes included in the plurality of light-emitting elements may be separated from each other by the separator.

In an embodiment, the driving element layer may further include a power line that receives a power voltage, the first electrode may be electrically connected to the power line, and the second electrode may be connected to the pixel driver.

In an embodiment, the driving element layer may further include a power line that receives a power voltage, the first electrode may be connected to the pixel driver, and the second electrode may be electrically connected to the power line.

In an embodiment of the inventive concept, a display panel includes: a driving element layer including a pixel driver; a plurality of light-emitting elements disposed on the driving element layer; a pixel defining film disposed on the driving element layer and having a plurality of openings aligned with the plurality of light-emitting elements; a separator disposed on the pixel defining film and dividing the display panel into regions in which the plurality of light-emitting elements are disposed; and a plurality of spacers disposed on the separator and spaced apart from each other, wherein a portion of an upper surface of the separator may be exposed between the plurality of spacers.

In an embodiment, the plurality of light-emitting elements may include a plurality of first electrodes, a plurality of intermediate layers disposed on the plurality of first electrodes, and a plurality of second electrodes disposed on the plurality of intermediate layers, wherein the plurality of intermediate layers may be separated from each other by the separator, and the plurality of second electrodes may be separated from each other by the separator, wherein the separator may include a first portion including a first side surface having a first taper angle and a second portion including a second side surface having a second taper angle different from the first taper angle, wherein a width of the first portion may be greater than a width of the second portion, and the plurality of spacers may be disposed on the first portion that is between the plurality of spacers and the second portion.

In an embodiment, when viewed on a plane, the separator may include a plurality of first lines extending in a first direction and a plurality of second lines extending in a second direction that crosses the first direction, and the plurality of spacers may be spaced apart from each other in at least one of the first direction and the second direction.

In an embodiment of the inventive concept, an electronic device includes a display panel, the display panel includes: a driving element layer including a pixel driver and a power line that receives a power voltage; a light-emitting element disposed on the driving element layer and including a first electrode, an intermediate layer disposed on the first electrode, and a second electrode disposed on the intermediate layer; a pixel defining film disposed on the driving element layer and having an opening that exposes to at least a portion of the first electrode; a separator disposed on the pixel defining film and surrounding at least a portion of the opening; and a plurality of spacers disposed on the separator and spaced apart from each other, wherein the plurality of spacers may be disposed to be spaced apart from each other on the separator, and a portion of an upper surface of the separator may be exposed between the plurality of spacers.

In an embodiment, the separator may include a first portion including a first side surface having a first taper angle and a second portion including a second side surface having a second taper angle different from the first taper angle, wherein the width of the first portion may be greater than the width of the second portion, and the plurality of spacers may be spaced apart from the second portion with the first portion interposed therebetween.

In an embodiment, the display panel may further include a connection electrode disposed between the pixel defining film and the separator, and the second electrode may be connected to the connection electrode adjacent to a side surface of the separator.

### BRIEF DESCRIPTION OF THE FIGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

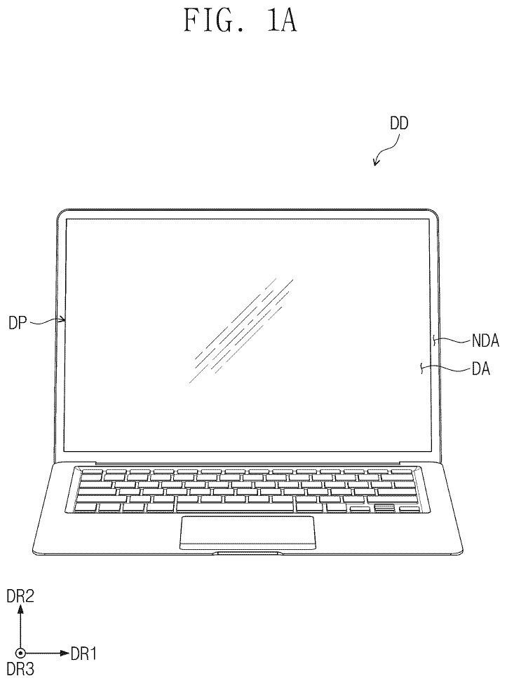

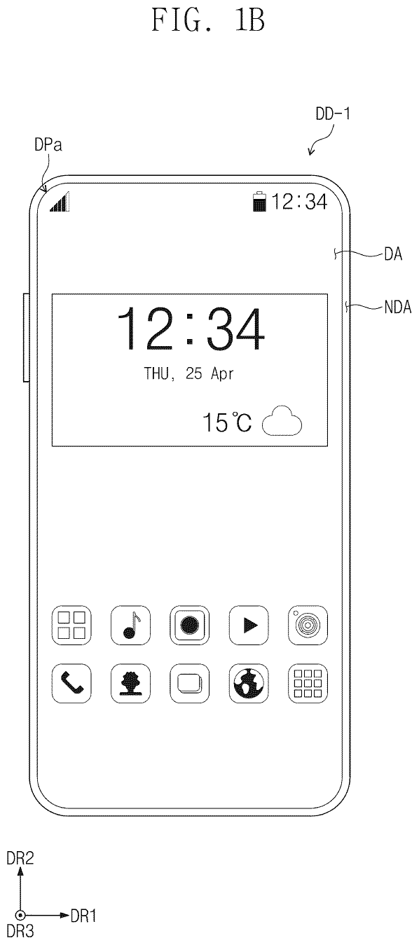

FIG. 1A is a perspective view of a display device according to an embodiment of the inventive concept;

FIG. 1B is a plan view of a display device according to an embodiment of the inventive concept;

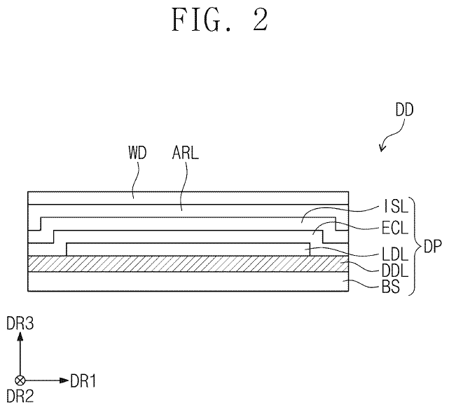

FIG. 2 is a schematic cross-sectional view of a display device according to an embodiment of the inventive concept;

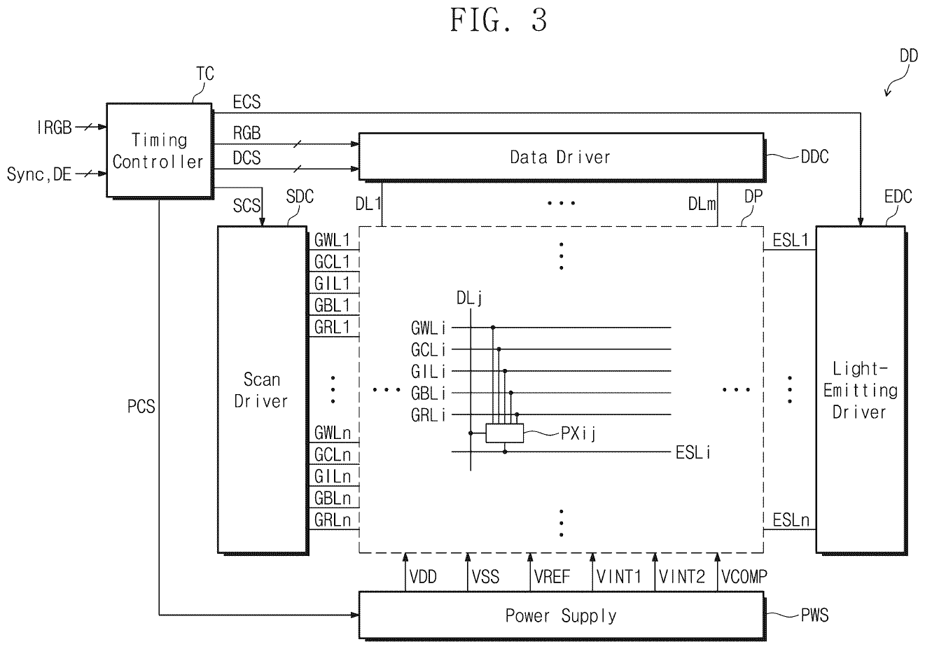

FIG. 3 is a block diagram of the display device according to an embodiment of the inventive concept;

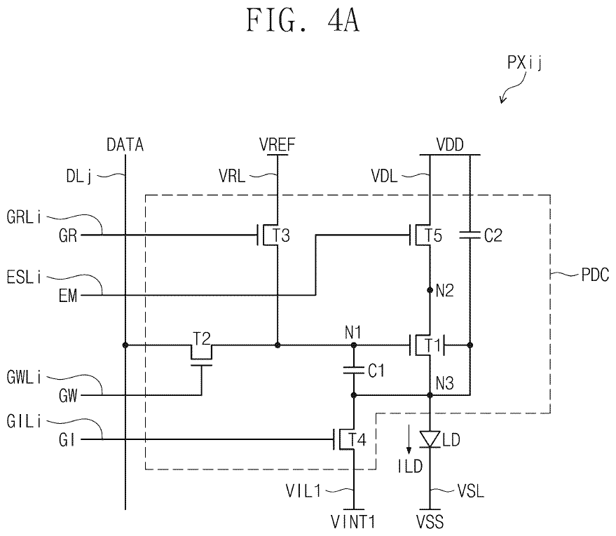

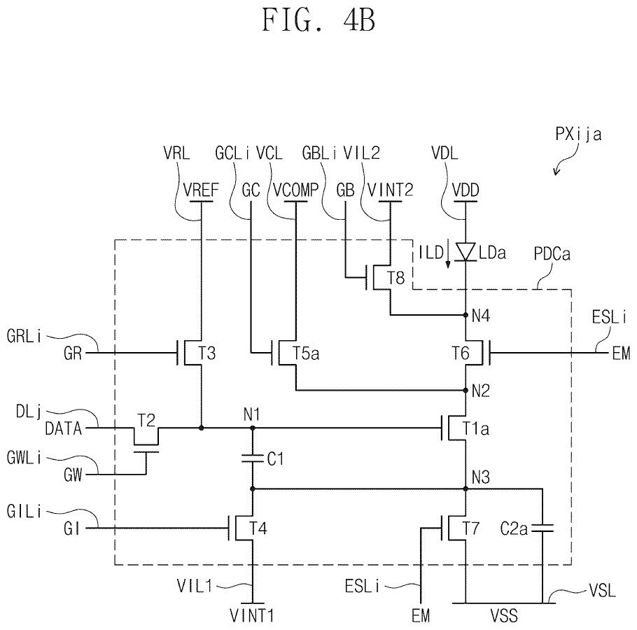

FIG. 4A is an equivalent circuit diagram of a pixel according to an embodiment of the inventive concept;

FIG. 4B is an equivalent circuit diagram of a pixel according to an embodiment of the inventive concept;

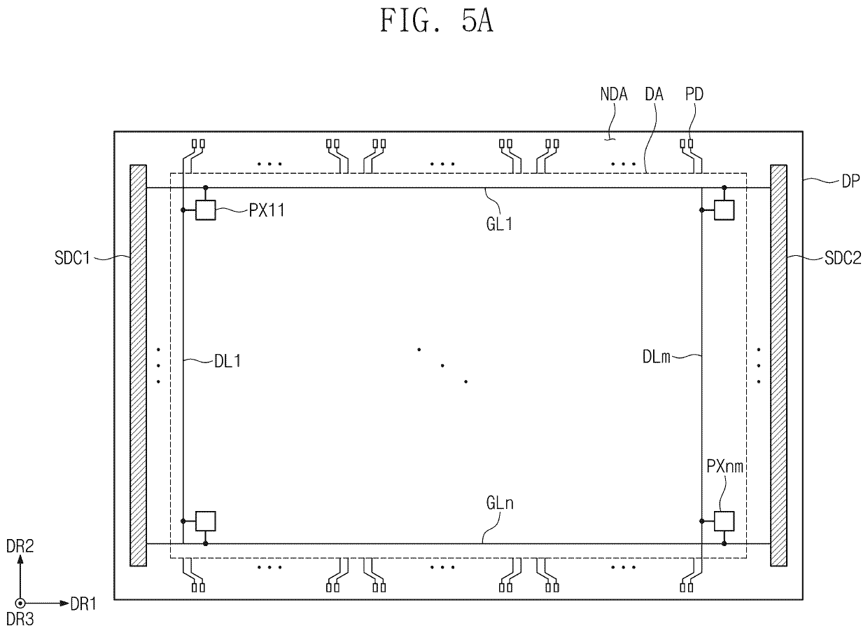

FIG. 5A is a schematic plan view of a display panel according to an embodiment of the inventive concept;

FIG. 5B is a schematic plan view of a display panel according to an embodiment of the inventive concept;

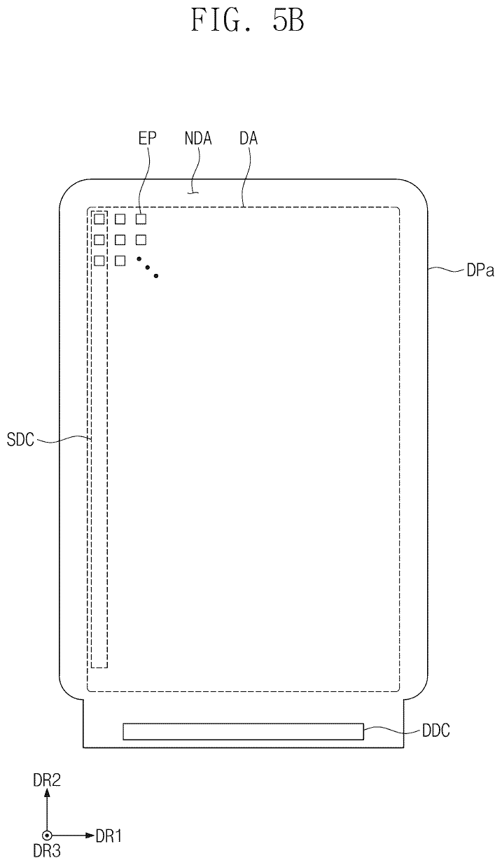

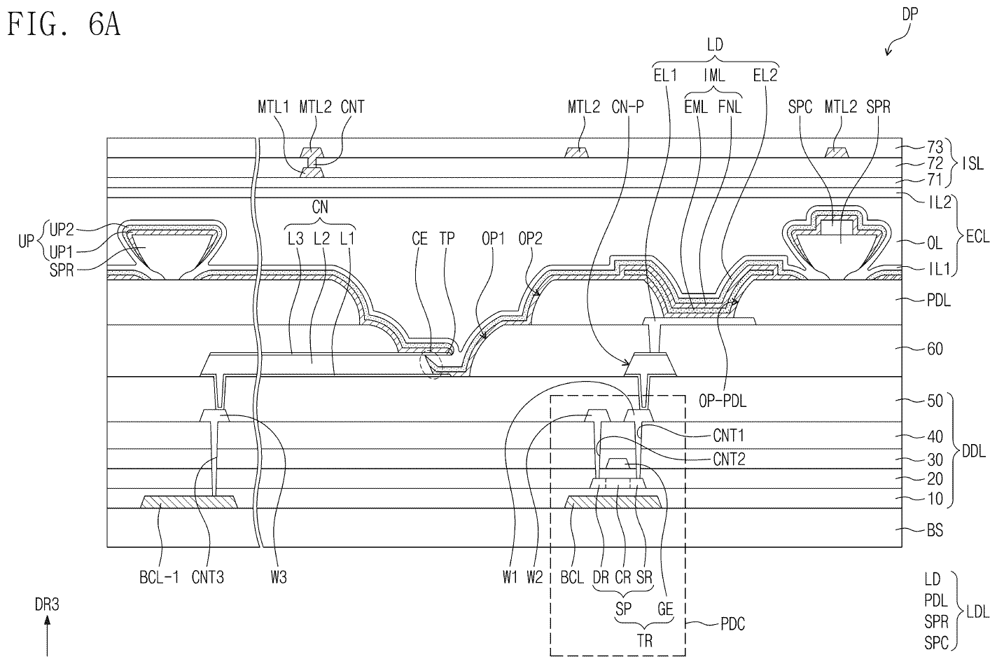

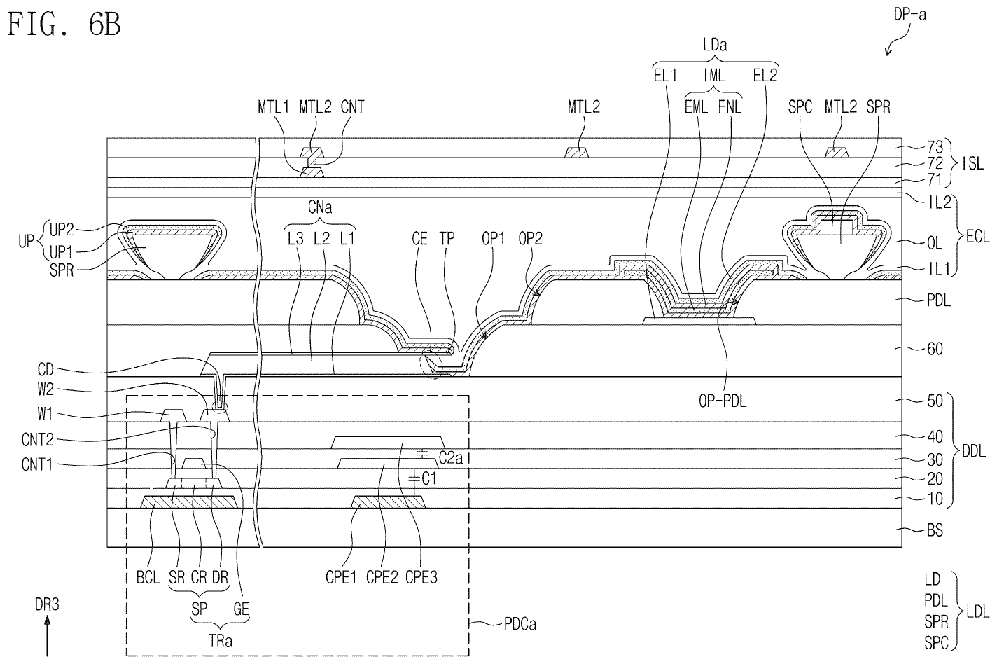

FIG. 6A is a cross-sectional view of a display panel according to an embodiment of the inventive concept;

FIG. 6B is a cross-sectional view of a display panel according to an embodiment of the inventive concept;

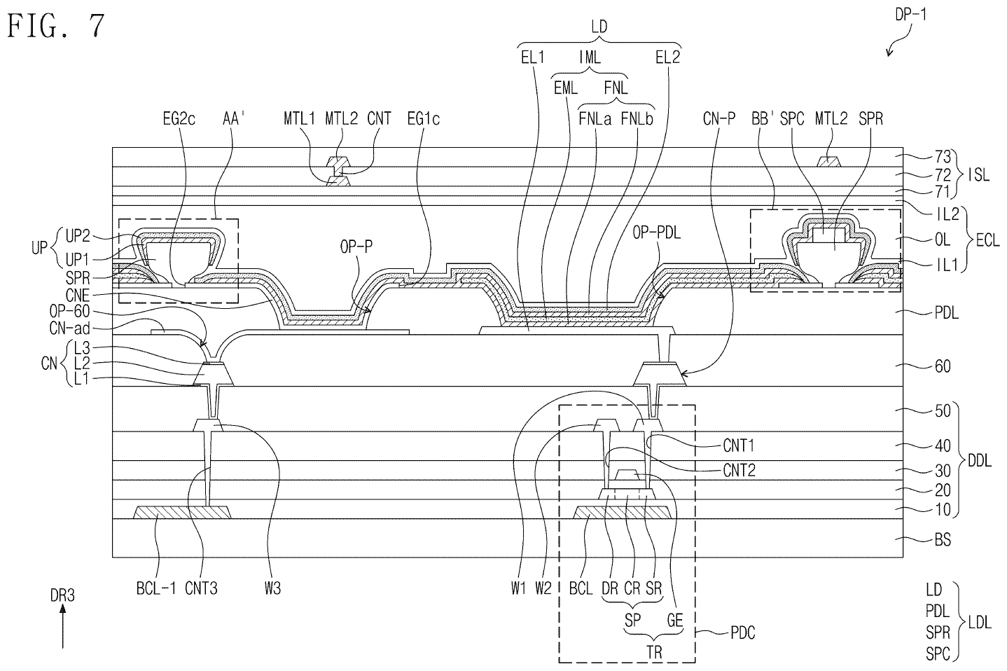

FIG. 7 is a cross-sectional view of a display panel according to an embodiment of the inventive concept;

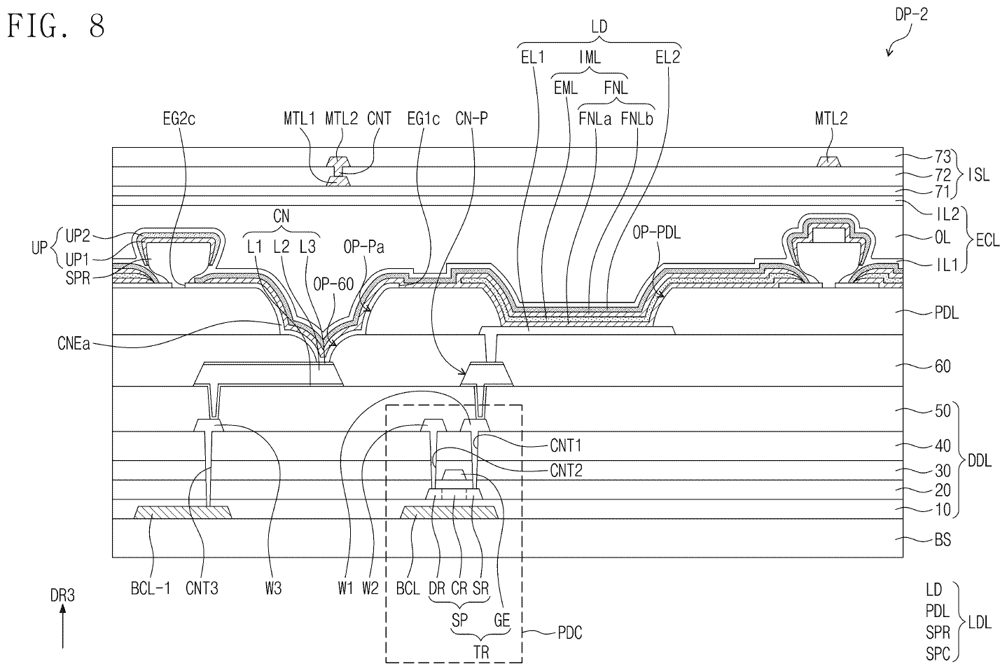

FIG. 8 is a cross-sectional view of a display panel according to an embodiment of the inventive concept;

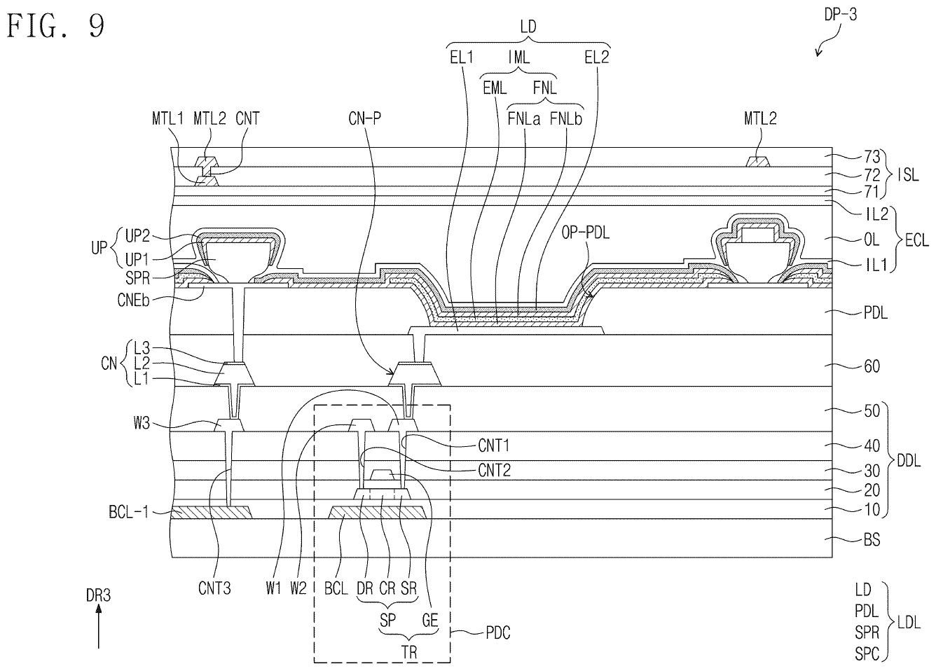

FIG. 9 is a cross-sectional view of a display panel according to an embodiment of the inventive concept;

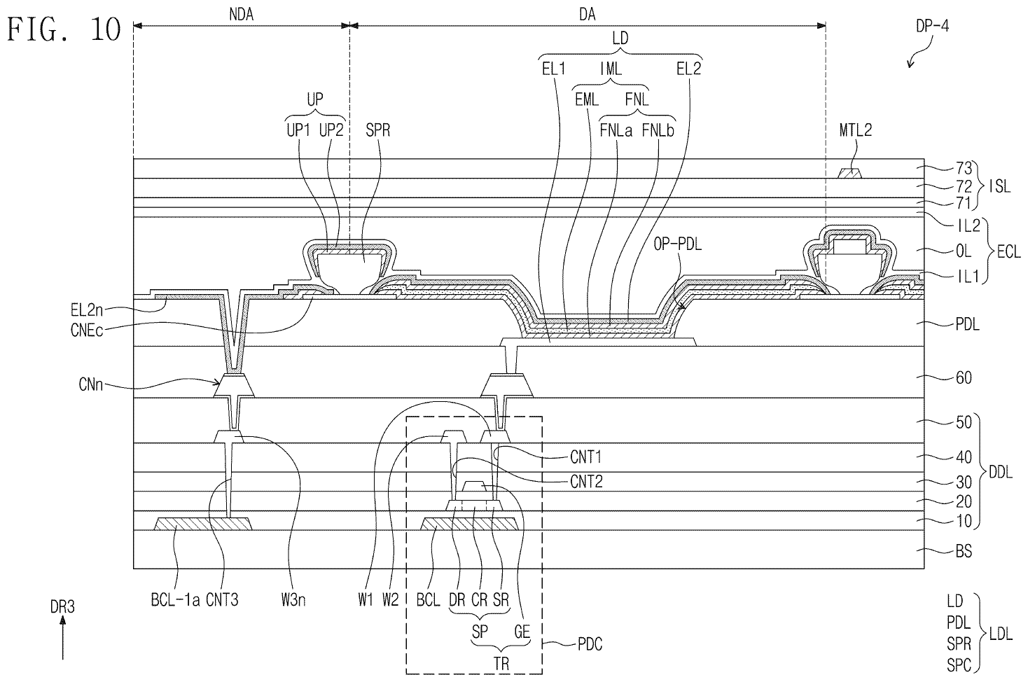

FIG. 10 is a cross-sectional view of a display panel according to an embodiment of the inventive concept;

FIG. 11A is an enlarged cross-sectional view of a partial region of a display panel according to an embodiment of the inventive concept;

FIG. 11B is a captured image of a partial region of the display panel according to an embodiment of the inventive concept;

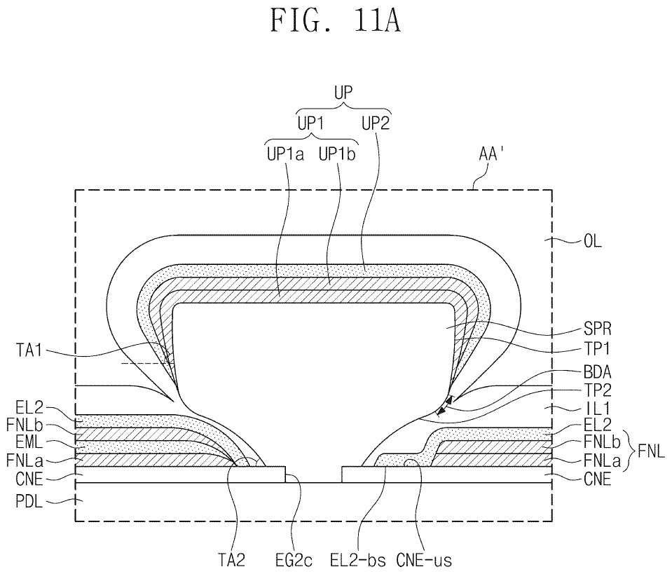

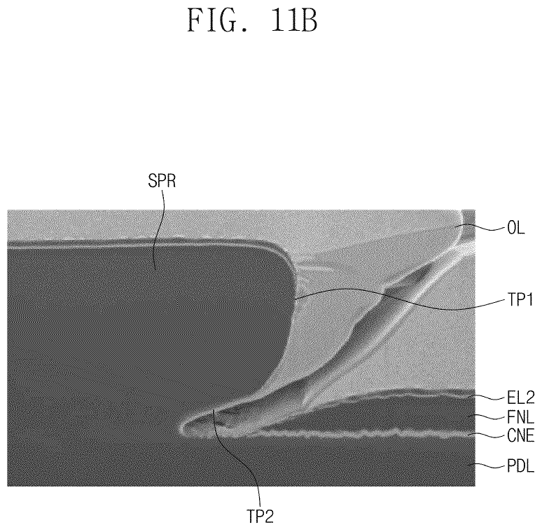

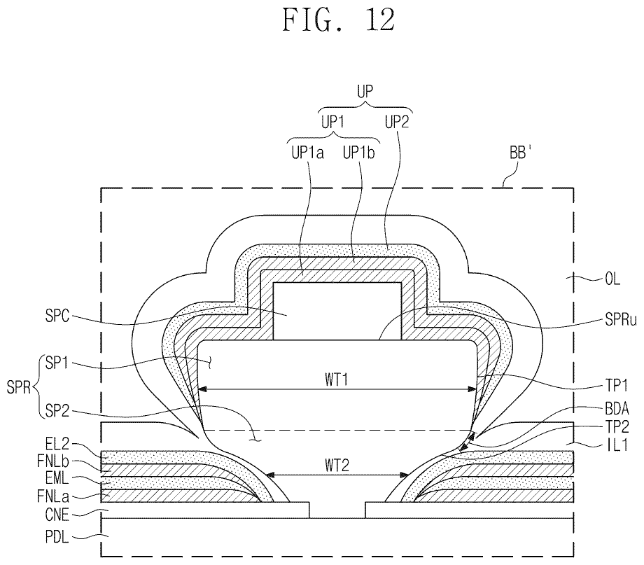

FIG. 12 is an enlarged cross-sectional view of a partial region of the display panel according to an embodiment of the inventive concept;

FIG. 13 is an enlarged plan view of a partial region of a display panel according to an embodiment of the inventive concept;

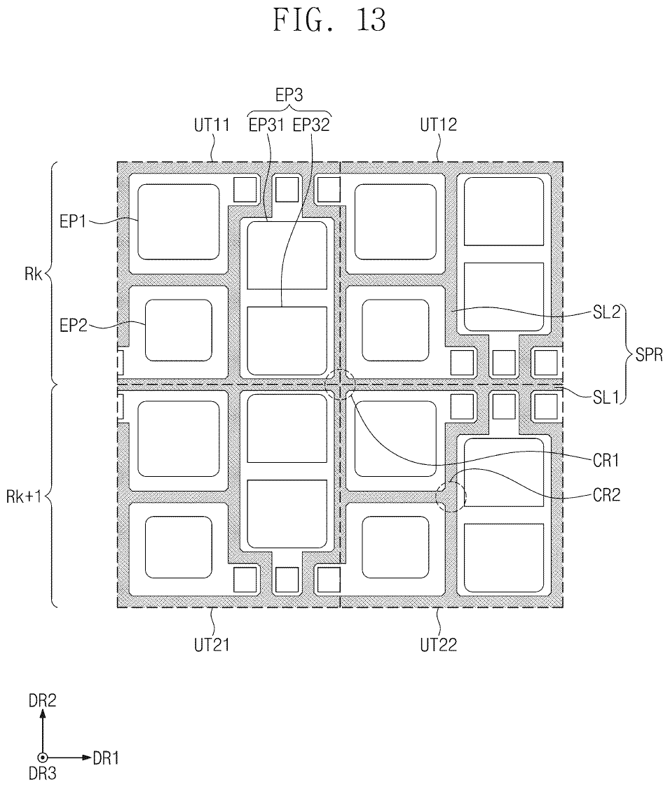

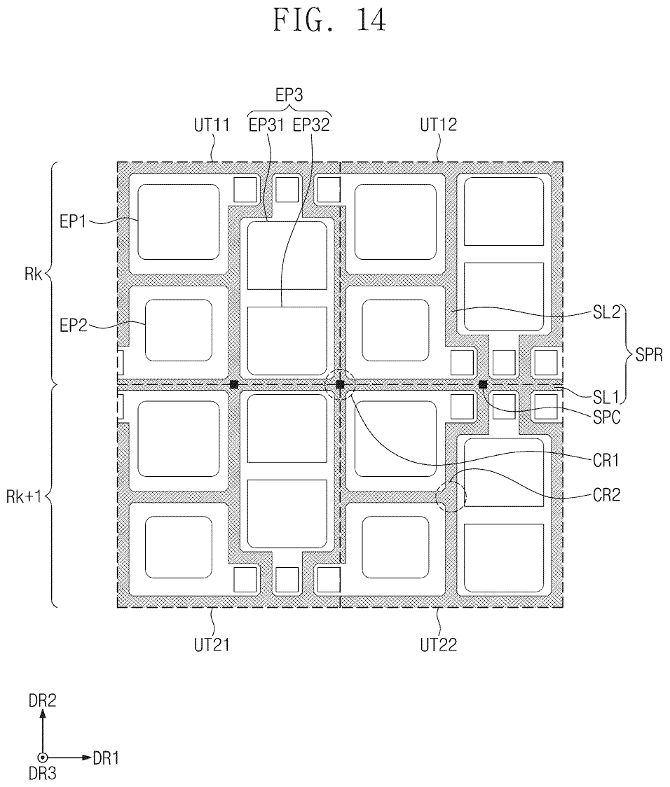

FIG. 14 is an enlarged plan view of a partial region of the display panel according to an embodiment of the inventive concept;

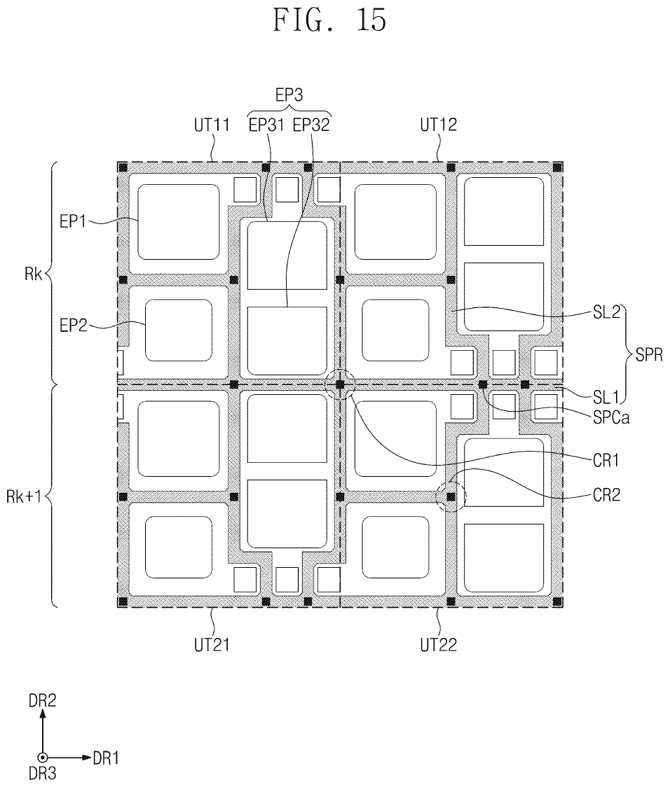

FIG. 15 is an enlarged plan view of a partial region of the display panel according to an embodiment of the inventive concept;

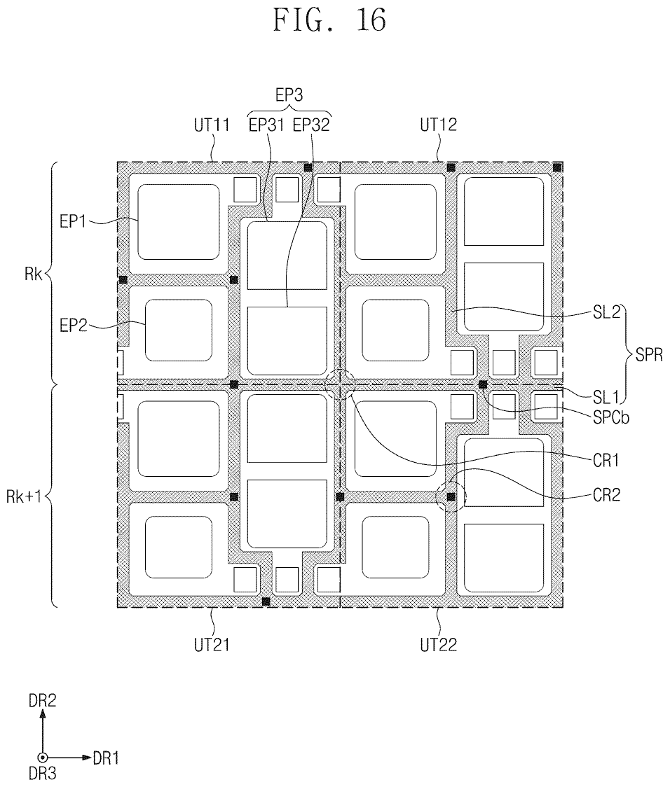

FIG. 16 is an enlarged plan view of a partial region of the display panel according to an embodiment of the inventive concept;

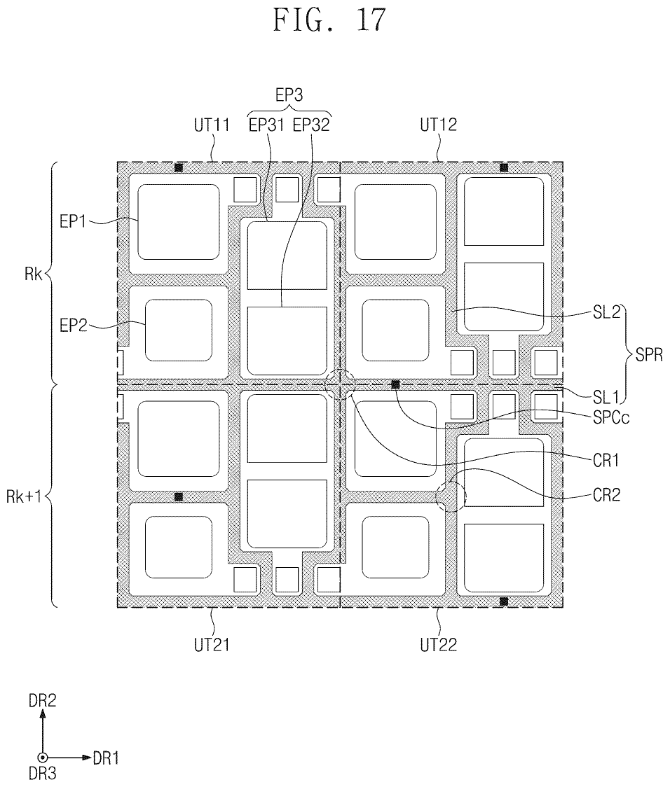

FIG. 17 is an enlarged plan view of a partial region of the display panel according to an embodiment of the inventive concept;

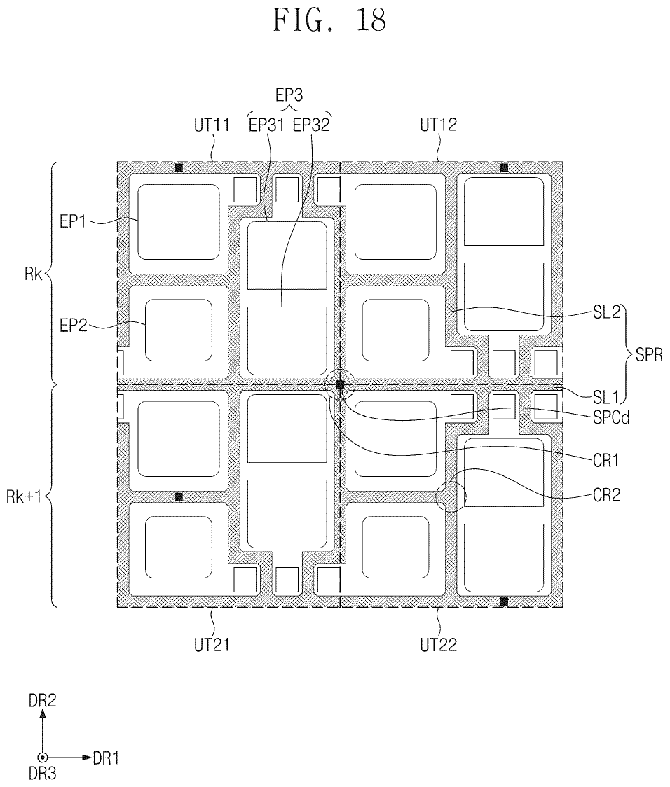

FIG. 18 is an enlarged plan view of a partial region of the display panel according to an embodiment of the inventive concept; and

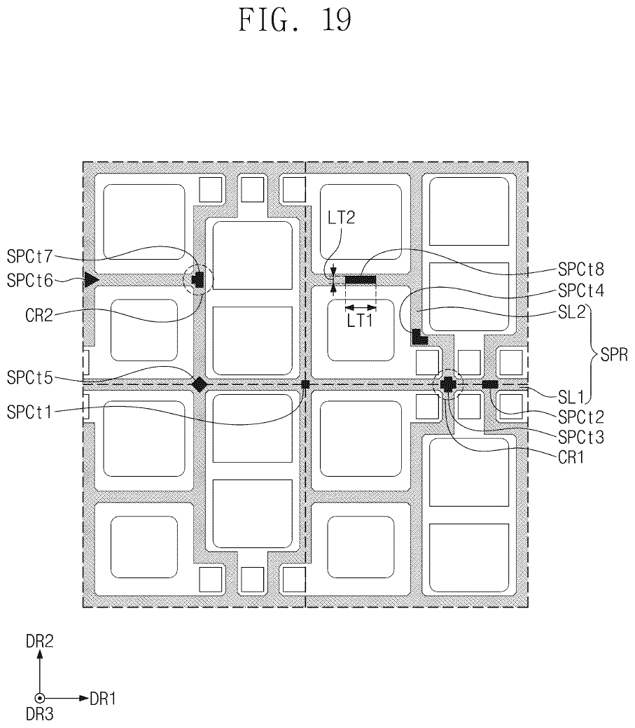

FIG. 19 is an enlarged plan view of a partial region of the display panel according to an embodiment of the inventive concept.

### DETAILED DESCRIPTION

In this specification, it will be understood that when an element (or region, layer, portion, etc.) is referred to as being “on”, “connected to” or “coupled to” another element, it can be directly on, connected or coupled to the other element, or intervening elements may be present.

Like reference numerals refer to like elements throughout. In addition, in the drawings, the thicknesses, ratios, and dimensions of elements are exaggerated for effective description of the technical contents. As used herein, the term “and/or” includes any and all combinations that the associated configurations can define.

It will be understood that, although the terms first, second, etc. may be used herein to describe various elements, these elements are not limited to any order or priority by these terms. These terms are used to distinguish one element from another element. For example, a first element could be termed a second element without departing from the scope of the present invention. Similarly, the second element may also be referred to as the first element. The terms of a singular form include plural forms unless otherwise specified.

In addition, terms, such as “below”, “lower”, “above”, “upper” and the like, are used herein for ease of description to describe one element's relation to another element(s) as illustrated in the figures. The above terms are relative concepts and are described based on the directions indicated in the drawings.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The term “part” or “unit” refers to a software component or hardware component that performs a specific function. The hardware component may include, for example, a field-programmable gate array (FPGA) or an application-specific integrated circuit (ASIC). The software component may refer to an executable code and/or data used by the executable code in an addressable storage medium. Accordingly, the software components may be, for example, object-oriented software components, class components, and task components, and may include processes, functions, attributes, procedures, subroutines, program code segments, drivers, firmware, micro codes, data, databases, data structures, tables, arrays or variables.

Hereinafter, embodiments of the inventive concept will be described with reference to the drawings.

FIG. 1A is a perspective view of a display device DD according to an embodiment of the inventive concept.

Referring to FIG. 1A, the display device DD may be activated according to an electrical signal. The display device DD may be used not only for large electronic devices such as televisions or outdoor billboards, but also for small- and medium-sized electronic devices such as personal computers, notebook computers, personal digital terminals, car navigation units, game consoles, portable electronic devices, and cameras. In addition, these are presented only as examples, and of course, the display device DD can be applied to other electronic devices as long as they do not depart from the concept of the present invention. FIG. 1A exemplarily illustrates that the display device DD is a notebook computer.

The display device DD may include a display panel DP. The display panel DP may be configured to substantially generate images. The display panel DP may be a light-emitting display panel. For example, the display panel DP may be an organic light-emitting display panel, an inorganic light-emitting display panel, an organic-inorganic light-emitting display panel, a quantum dot display panel, a micro LED display panel, or a nano LED display panel.

In addition, in an embodiment of the inventive concept, the display panel DP may further include a function for sensing an external input. For example, the display panel DP may be configured to sense at least one of an active input by an input device or a passive input by touch. The touch may include any input means that can provide a change in capacitance, such as a user's body or an input device (e.g., a pen).

A display region DA and a peripheral region NDA may be defined in the display panel DP. The display panel DP may display an image through the display region DA. The display region DA may include a surface defined by a first direction DR1 and a second direction DR2. The peripheral region NDA may surround the display region DA. In an embodiment of the inventive concept, the peripheral region NDA may be omitted.

The thickness direction of the display panel DP may be parallel to a third direction DR3 that crosses the first direction DR1 and the second direction DR2. Accordingly, the front (or upper) and rear (or lower) surfaces of the members constituting the display panel DP may be defined based on the third direction DR3.

FIG. 1B is a plan view of a display device DD-1 according to an embodiment of the inventive concept.

FIG. 1B exemplarily illustrates that the display device DD-1 is a bar-type mobile phone. The display device DD-1 may include a display panel DPa. Although FIG. 1B illustrates a bar-type display device DD-1 as an example, the embodiment of the inventive concept is not limited thereto. For example, descriptions provided below may be applied to various electronic devices such as a foldable display device, a rollable display device, or a slidable display device.

FIG. 2 is a schematic cross-sectional view of the display device DD according to an embodiment of the inventive concept.

Referring to FIG. 2, the display device DD may include a display panel DP, an anti-reflection layer ARL, and a window WD. The display panel DP may include a base layer BS, a driving element layer DDL, a light-emitting element layer LDL, an encapsulation layer ECL, and a sensing layer ISL.

The base layer BS may be a member that provides a base surface on which the driving element layer DDL is disposed. The base layer BS may be a rigid substrate or a flexible substrate capable of being bent, folded, or rolled. The base layer BS may be a glass substrate, a metal substrate, a silicon substrate, or a polymer substrate. However, the embodiment of the inventive concept is not limited thereto, and the base layer BS may be an inorganic layer, an organic layer, or a composite material layer.

The driving element layer DDL may be disposed on the base layer BS. The driving element layer DDL may include an insulating layer, a semiconductor pattern, a conductive pattern, a signal line, and the like. For example, the driving element layer DDL may include a power line that receives a power voltage. An insulating layer, a semiconductor layer, and a conductive layer may be formed on the base layer BS by coating, deposition, or the like, and then the insulating layer, the semiconductor layer, and the conductive layer may be selectively patterned through multiple photolithography processes. Hereafter, the semiconductor pattern, the conductive pattern, and the signal line included in the driving element layer DDL may be formed.

The light-emitting element layer LDL may be disposed on the driving element layer DDL. The light-emitting element layer LDL may include a light-emitting element. For example, the light-emitting element layer LDL may include an organic light-emitting material, an inorganic light-emitting material, an organic-inorganic light-emitting material, quantum dots, quantum rods, micro LEDs, or nano LEDs.

The encapsulation layer ECL may be disposed on the light-emitting element layer LDL. The encapsulation layer ECL may protect the light-emitting element layer LDL from moisture, oxygen, and foreign substances such as dust particles.

The sensing layer ISL may be disposed on the encapsulation layer ECL. The sensing layer ISL may be formed on the encapsulation layer ECL through a continuous process. In this case, the sensing layer ISL may be expressed as being directly disposed on the encapsulation layer ECL. Being directly disposed may mean that no third component is disposed between the sensing layer ISL and the encapsulation layer ECL. That is, a separate adhesive member may not be disposed between the sensing layer ISL and the encapsulation layer ECL. Alternatively, the sensing layer ISL may be coupled to the encapsulation layer ECL by an adhesive member. The adhesive member may include a conventional adhesive or glue agent. The anti-reflection layer ARL may be disposed on the sensing layer ISL.

The anti-reflection layer ARL may reduce the reflectance of external light incident from the outside of the display device DD (see FIG. 1A). The anti-reflection layer ARL may be disposed directly on the sensing layer ISL. Without being a limitation thereto, however, an adhesive member may be disposed between the anti-reflection layer ARL and the sensing layer ISL.

The anti-reflection layer ARL may include color filters. The color filters may have a predetermined arrangement. For example, the color filters may be arranged in consideration of the light-emitting colors of pixels included in a display layer. In addition, the anti-reflection layer ARL may further include a black matrix adjacent to the color filters.

Alternatively, the anti-reflection layer ARL may include a reflection adjustment layer. The reflection adjustment layer may selectively absorb some bands of light among light reflected from the inside of a display panel DP and/or an electronic device or light incident from the outside of the display panel DP and/or the electronic device. For example, by absorbing light outside the wavelength ranges of red, green, or blue among light emitted from the display panel DP, the reflection adjustment layer may prevent or minimize a decrease in luminance of the display panel DP and/or the electronic device. In addition, at the same time, a decrease in luminous efficiency of the display panel DP and/or the electronic device may be prevented or minimized, and visibility may be improved.

Alternatively, the anti-reflection layer ARL may include a retarder and/or a polarizer. In this case, the anti-reflection layer ARL may be attached to the sensing layer ISL by an adhesive layer. The retarder may be a film type or a liquid crystal coating type and include a N/2 retarder and/or a N/4 retarder. The polarizer may also be a film type and include a stretchable synthetic resin film. The retarder and the polarizer may further include a protective film. The retarder and the polarizer themselves or the protective film may be defined as a base layer of the anti-reflection layer ARL.

The window WD may be disposed on the anti-reflection layer ARL. An adhesive member may be disposed between the anti-reflection layer ARL and the window WD, but these arrangements are not limitations of the inventive concept. The window WD may include an optically transparent insulating material. For example, the window WD may include glass or plastic. The window WD may have a multi-layer structure or a single-layer structure. For example, the window WD may include a plurality of plastic films bonded to each other by an adhesive, or may include a glass substrate and a plastic film bonded to each other by an adhesive.

FIG. 3 is a block diagram of the display device DD according to an embodiment of the inventive concept.

Referring to FIG. 3, the display device DD may include a display panel DP, a panel driving unit SDC, EDC, and DDC, a power supply PWS, and a timing controller TC. In this embodiment, the display panel DP is described as a light-emitting display panel. The light-emitting display panel may include an organic light-emitting display panel, an inorganic light-emitting display panel, or a quantum dot light-emitting display panel. In an embodiment of the inventive concept to be described later, the organic light-emitting display panel will be described in detail as an example. The panel driving unit SDC, EDC, and DDC may include a scan driver SDC, a light-emitting driver EDC, and a data driver DDC.

The display panel DP may include scan lines GWL1 to GWLn, GCL1 to GCLn, GIL1 to GILn, GBL1 to GBLn, and GRL1 to GRLn, light-emitting lines ESL1 to ESLn, and data lines DL1 to DLm. The display panel DP may include a plurality of pixels connected to the scan lines GWL1 to GWLn, GCL1 to GCLn, GIL1 to GILn, GBL1 to GBLn, and GRL1 to GRLn, the light-emitting lines ESL1 to ESLn, and the data lines DL1 to DLm (wherein m and n are integers greater than 1).

For example, a pixel PXij (i and j are integers greater than 1) located on an i-th horizontal line (or an i-th pixel row) and a j-th vertical line (or a j-th pixel column) may be connected to an i-th first scan line GWLi (or write scan line), an i-th second scan line GCLi (or compensation scan line), an i-th third scan line GILi (or first initialization scan line), an i-th fourth scan line GBLi (or second initialization scan line), an i-th fifth scan line GRLi (or reset scan line), a j-th data line DLj, and an i-th light-emitting line ESLi.

The pixel PXij may include a plurality of light-emitting elements, a plurality of transistors, and a plurality of capacitors. The pixel PXij may receive, through the power supply PWS, a first power voltage VDD, a second power voltage VSS, a third power voltage VREF (or reference voltage), a fourth power voltage VINT1 (or first initialization voltage), a fifth power voltage VINT2 (or second initialization voltage), and a sixth power voltage VCOMP (or compensation voltage).

The voltage values of the first power voltage VDD and the second power voltage VSS are set so that current can flow into a light-emitting element, allowing it to emit light. For example, the first power voltage VDD may be set to a voltage higher than the second power voltage VSS.

The third power voltage VREF may be a voltage for initializing the gate of a driving transistor included in the pixel PXij. The third power voltage VREF may be used to implement a predetermined gradation by using a voltage difference between a data signal and the third power voltage VREF. To this end, the third power voltage VREF may be set to a predetermined voltage within the voltage range of the data signal.

The fourth power voltage VINT1 may be a voltage for initializing a capacitor included in the pixel PXij. The fourth power voltage VINT1 may be set to a voltage lower than the third power voltage VREF. For example, the fourth power voltage VINT1 may be set to a voltage that is lower than the third power voltage VREF by at least a difference between the third power voltage VREF and a threshold voltage of the driving transistor. However, the embodiment of the inventive concept is not limited thereto.

The fifth power voltage VINT2 may be a voltage for initializing a cathode of the light-emitting element included in the pixel PXij. The fifth power voltage VINT2 may be set to a voltage lower than the first power voltage VDD or the fourth power voltage VINT1, or may be set to a voltage similar to or equal to the third power voltage VREF, but the embodiment of the inventive concept is not limited thereto, and the fifth power voltage VINT2 may be set to a voltage similar to or equal to the first power voltage VDD.

The sixth power voltage VCOMP may supply a predetermined current to the driving transistor when compensating for the threshold voltage of the driving transistor.

FIG. 3 illustrates that the first to sixth power voltages VDD, VSS, VREF, VINT1, VINT2, and VCOMP are all supplied from the power supply PWS, but the embodiment of the inventive concept is not limited thereto. For example, the first power voltage VDD and the second power voltage VSS are all supplied regardless of the structure of the pixel PXij, and at least one of the third power voltage VREF, the fourth power voltage VINT1, the fifth power voltage VINT2, and the sixth power voltage VCOMP may not be supplied depending on the structure of the pixel PXij.

In an embodiment of the inventive concept, signal lines connected to the pixel PXij may be set in various ways according to a circuit structure of the pixel PXij.

The scan driver SDC may receive a first control signal SCS from the timing controller TC and, based on the first control signal SCS, supply a scan signal to each of the first scan lines GWL1 to GWLn, the second scan lines GCL1 to GCLn, the third scan lines GIL1 to GILn, the fourth scan lines GBL1 to GBLn, and the fifth scan lines GRL1 to GRLn.

The scan signal may be set to a voltage at which transistors that receive the scan signal may be turned on. For example, a scan signal supplied to a P-type transistor may be set to a logic low level, and a scan signal supplied to an N-type transistor may be set to a logic high level. Hereinafter, the expression “a scan signal is supplied” may mean that the scan signal is supplied with a logic level that turns on a transistor which is controlled by the scan signal.

FIG. 3 illustrates, for the convenience of explanation, that the scan driver SDC is a single element, but the embodiment of the inventive concept is not limited thereto. According to an embodiment of the inventive concept, a plurality of scan drivers may be included to supply a scan signal to each of the first scan lines GWL1 to GWLn, the second scan lines GCL1 to GCLn, the third scan lines GIL1 to GILn, the fourth scan lines GBL1 to GBLn, and the fifth scan lines GRL1 to GRLn.

The light-emitting driver EDC may supply a light-emitting signal to the light-emitting lines ESL1 to ESLn, based on a second control signal ECS. For example, the light-emitting signal may be sequentially supplied to the light-emitting lines ESL1 to ESLn.

Transistors connected to the light-emitting lines ESL1 to ESLn according to an embodiment of the inventive concept may be composed of N-type transistors. In this case, the light-emitting signal supplied to the light-emitting lines ESL1 to ESLn may be set to a gate-on voltage. Transistors that receive the light-emitting signal may turn on in response to receiving the light-emitting signal. In the absence of a light-emitting signal, the transistors may be set to a turned-off state. In another embodiment of the inventive concept, the light-emitting signal supplied to the light-emitting lines ESL1 to ESLn may be set to a gate-off voltage. Transistors that receive the light-emitting signal may turn off in response to receiving the light-emitting signal. In the absence of a light-emitting signal, the transistors may be set to a turned-on state.

The second control signal ECS may include a light-emitting start signal and clock signals, and the light-emitting driver EDC may be implemented as a shift register which sequentially generates and outputs the light-emitting signal in a pulse form by sequentially shifting the light-emitting start signal in a pulse form with the use of the clock signals.

The data driver DDC may receive a third control signal DCS and image data RGB from the timing controller TC. The data driver DDC may convert the image data RGB in digital form into an analog data signal (i.e., a data signal). The data driver DDC may supply the data signal to the data lines DL1 to DLm in response to the third control signal DCS.

The third control signal DCS may include a data enable signal, a horizontal start signal, a data clock signal, and the like which command the output of a valid data signal. For example, the data driver DDC may include a shift register configured to generate a sampling signal by shifting the horizontal start signal in synchronization with the data clock signal, a latch configured to latch the image data RGB in response to the sampling signal, a digital-to-analog converter (or decoder) configured to convert the latched image data RGB (e.g., data in digital form) into data signals in analog form, and buffers (or amplifiers) configured to output the data signals to the data lines DL1 to DLm.

The power supply PWS may supply the display panel DP with the first power voltage VDD, the second power voltage VSS, and the third power voltage VREF for driving the pixel PXij. In addition, the power supply PWS may supply the display panel DP with at least one of the fourth power voltage VINT1, the fifth power voltage VINT2, or the sixth power voltage VCOMP.

For example, the power supply PWS may supply the display panel DP with the first power voltage VDD, the second power voltage VSS, the third power voltage VREF, the fourth power voltage VINT1, the fifth power voltage VINT2, and the sixth power voltage VCOMP respectively via a first power line VDL (see FIG. 4A), a second power line VSL (see FIG. 4A), a third power line VRL (or reference voltage line, see FIG. 4A), a fourth power line VIL1 (or first initialization voltage line, see FIG. 4A), a fifth power line VIL2 (or second initialization voltage line, see FIG. 4B), and a sixth power line VCL (or compensation voltage line, see FIG. 4B) which are not illustrated.

The power supply PWS may be implemented as a power management integrated circuit, but the embodiment of the inventive concept is not limited thereto.

The timing controller TC may generate a first control signal SCS, a second control signal ECS, a third control signal DCS, and a fourth control signal PCS, based on an input image data IRGB, a sync signal Sync (e.g., a vertical sync signal, a horizontal sync signal, etc.), a data enable signal DE, a clock signal, and the like. The first control signal SCS may be supplied to the scan driver SDC, the second control signal ECS may be supplied to the light-emitting driver EDC, the third control signal DCS may be supplied to the data driver DDC, and the fourth control signal PCS may be supplied to the power supply PWS. The timing controller TC may rearrange the input image data IRGB so as to correspond to the arrangement of the pixels PXij in the display panel DP to generate image data RGB (or frame data).

The scan driver SDC, the light-emitting driver EDC, the data driver DDC, the power supply PWS, and/or the timing controller TC may be formed directly on the display panel DP or provided in the form of a separate driving chip and connected to the display panel DP. In addition, at least two of the scan driver SDC, the light-emitting driver EDC, the data driver DDC, the power supply PWS, and the timing controller TC may be provided as one driving chip. For example, the data driver DDC and the timing controller TC may be provided as one driving chip.

In the above, the display device DD according to an embodiment of the inventive concept has been described with reference to FIG. 3, but the display device according to this inventive concept is not limited thereto. More signal lines may be added or some signal lines may be omitted according to the configuration of the pixels. In addition, a connection relationship between one pixel and signal lines may be changed. If any one of the signal lines is omitted, another signal line may substitute for the omitted signal line.

FIG. 4A is an equivalent circuit diagram of a pixel PXij according to an embodiment of the inventive concept.

FIGS. 3 and 4A illustrate an example of the equivalent circuit diagram of the pixel PXij connected to the i-th first scan line GWLi (hereinafter referred to as a first scan line) and the j-th data line DLj (hereinafter referred to as a data line).

The pixel PXij includes a light-emitting element LD and a pixel driver PDC. The light-emitting element LD is connected to the second power line VSL and the pixel driver PDC.

The pixel driver PDC may be connected to a plurality of scan lines GWLi, GILi, and GRLi, a data line DLj, a light-emitting line ESLi, and a plurality of power voltage lines VDL, VSL, VIL1, and VRL.

The pixel driver PDC may include first to fifth transistors T1, T2, T3, T4, and T5, a first capacitor C1, and a second capacitor C2. Hereinafter, a case in which all of the first to fifth transistors T1, T2, T3, T4, and T5 are N types will be described as an example. However, the inventive concept is not limited thereto, and some of the first to fifth transistors T1, T2, T3, T4, and T5 may be N-type transistors, and others may be P-type transistors. Each of the first to fifth transistors T1, T2, T3, T4, and T5 may be a P-type transistor, and the inventive concept is not limited to any one embodiment. The pixel PXij illustrated in FIG. 4A is only one example, and the circuit configuration of the pixel PXij may be implemented after modification.

The gate of the first transistor T1 may be connected to a first node N1. The first electrode of the first transistor T1 may be connected to a second node N2, and the second electrode may be connected to a third node N3. The first transistor T1 may further include a back gate. The back gate of the first transistor T1 may be connected to the third node N3. The back gate of the first transistor T1 may be omitted.

The first transistor T1 may be a driving transistor. The first transistor T1 may control a driving current ILD flowing from the first power line VDL to the second power line VSL via the light-emitting element LD in response to a voltage of the first node N1. In this case, the first power voltage VDD may be set to a voltage having a higher potential than the second power voltage VSS.

In this specification, the expression “A transistor and a signal line, or a transistor and a transistor are electrically connected to each other.” means that the source, drain, and gate of a transistor that may be integrated with the signal line or may be connected to another such transistor through a connection electrode.

The second transistor T2 may include a gate connected to the write scan line GWLi, a first electrode connected to the data line DLj, and a second electrode connected to the first node N1. The second transistor T2 may supply a data signal DATA to the first node N1 in response to a write scan signal GW transmitted through the write scan line GWLi. When the write scan signal GW is supplied to the write scan line GWLi, the second transistor T2 may be turned on to electrically connect the data line DLj and the first node N1 to each other.

The third transistor T3 may be connected between the first node N1 and the reference voltage line VRL. The first electrode of the third transistor T3 may receive the reference voltage VREF through the reference voltage line VRL, and the second electrode of the third transistor T3 may be connected to the first node N1. In this embodiment, the gate of the third transistor T3 may receive a reset scan signal GR through the i-th fifth scan line GRLi (hereinafter referred to as a reset scan line). When the reset scan signal GR is supplied to the reset scan line GRLi, the third transistor T3 may be turned on to provide the reference voltage VREF to the first node N1.

The fourth transistor T4 may be connected between the third node N3 and the first initialization voltage line VIL1. The first electrode of the fourth transistor T4 may be connected to the third node N3, and the second electrode of the fourth transistor T4 may be connected to the first initialization voltage line VIL1 that provides the first initialization voltage VINT1. The fourth transistor T4 may be referred to as a first initialization transistor. The gate of the fourth transistor T4 may receive a first initialization scan signal GI through the i-th third scan line GILi (hereinafter referred to as a first initialization scan line). When the first initialization scan signal GI is supplied to the first initialization scan line GILi, the fourth transistor T4 may be turned on to supply the first initialization voltage VINT1 to the third node N3.

The fifth transistor T5 may be connected between the first transistor T1 and the first power line VDL. Specifically, the gate of the fifth transistor T5 may receive a light-emitting signal EM through the i-th light-emitting line ESLi (hereinafter referred to as a light-emitting line). The first electrode of the fifth transistor T5 may be connected to the first power line VDL, and the second electrode of the fifth transistor T5 may be connected to the first electrode of the first transistor T1 through the second node N2. The fifth transistor T5 may be referred to as a light-emitting control transistor. When the light-emitting signal EM is supplied to the light-emitting line ESLi, the fifth transistor T5 may be turned on and electrically connect the first transistor T1 and the first power line VDL to each other.

The first capacitor C1 may be disposed between the first node N1 and the third node N3. The first capacitor C1 may store a voltage that approximates to the voltage difference between the first node N1 and the third node N3. The first capacitor C1 may be referred to as a storage capacitor.

The second capacitor C2 may be disposed between the third node N3 and the first power line VDL. That is, one electrode of the second capacitor C2 may be connected to the first power line VDL that receives the first power voltage VDD, and the other electrode of the second capacitor C2 may be connected to the third node N3. The second capacitor C2 may store a charge that approximates to a voltage difference between the first power voltage VDD and the third node N3. The second capacitor C2 may be referred to as a hold capacitor. The second capacitor C2 may have a higher storage capacity than the first capacitor C1. Accordingly, the second capacitor C2 may minimize a voltage change of the third node N3 in response to a voltage change of the first node N1.

The light-emitting element LD may be connected between the pixel driver PDC and the second power line VSL. For example, the light-emitting element LD may be connected to the pixel driver PDC through the third node N3. The light-emitting element LD may include an anode connected to the pixel driver PDC and a cathode opposite to the anode. In this embodiment, the cathode of the light-emitting element LD may be connected to the second power line VSL.

FIG. 4B is an equivalent circuit diagram of a pixel PXija according to an embodiment of the inventive concept. In describing FIG. 4B, the same reference numerals will be given to the same components as described in FIG. 4A, and the descriptions thereof will be omitted.

FIG. 4B exemplarily illustrates the equivalent circuit diagram of the pixel PXija connected to the i-th first scan line GWLi (hereinafter referred to as a first scan line) and connected to the j-th data line DLj (hereinafter referred to as a data line).

The pixel PXija includes a light-emitting element LDa and a pixel driver PDCa. The light-emitting element LDa is connected to the first power line VDL and the pixel driver PDCa.

The pixel driver PDCa may be connected to a plurality of scan lines GWLi, GCLi, GILi, GBLi, and GRLi, a data line DLj, a light-emitting line ESLi, and a plurality of power voltage lines VDL, VSL, VIL1, VIL2, VRL, and VCL. The pixel driver PDCa may include first to eighth transistors T1a, T2, T3, T4, T5a, T6, T7, and T8, a first capacitor C1, and a second capacitor C2a. Hereinafter, a case in which all of the first to eighth transistors T1a, T2, T3, T4, T5a, T6, T7, and T8 are N-type is explained as an example. However, the embodiment of the inventive concept is not limited thereto, and some of the first to eighth transistors T1a, T2, T3, T4, T5a, T6, T7, and T8 may be N-type transistors, and the others may be P-type transistors. Alternatively, each of the first to eighth transistors T1a, T2, T3, T4, T5a, T6, T7, and T8 may be a P-type transistor and the inventive concept is not limited to any one embodiment.

The gate of the first transistor T1a may be connected to the first node N1. The first electrode of the first transistor T1a may be connected to the second node N2 and the second electrode may be connected to the third node N3. The first transistor T1a may be a driving transistor. The first transistor T1a may control a driving current ILD flowing from the first power line VDL to the second power line VSL via the light-emitting element LDa in response to a voltage of the first node N1. In this case, the first power voltage VDD may be set to a voltage having a higher potential than the second power voltage VSS.

The second transistor T2, the third transistor T3, and the fourth transistor T4 are substantially the same as those previously described with reference to FIG. 4A. Therefore, their descriptions are omitted.

The fifth transistor T5a may be connected between the compensation voltage line VCL and the second node N2. The first electrode of the fifth transistor T5a may receive a compensation voltage VCOMP through the compensation voltage line VCL, and the second electrode of the fifth transistor T5a may be connected to the second node N2 so as to be electrically connected to the first electrode of the first transistor T1a. The gate of the fifth transistor T5a may receive a compensation scan signal GC through the i-th second scan line GCLi (hereinafter referred to as a compensation scan line). When the compensation scan signal GC is supplied to the compensation scan line GCLi, the fifth transistor T5a may be turned on so as to be able to provide the compensation voltage VCOMP to the second node N2, and a threshold voltage of the first transistor T1a may be compensated for during a compensation period.

The sixth transistor T6 may be connected between the first transistor T1a and the light-emitting element LDa. Specifically, the gate of the sixth transistor T6 may receive a light-emitting signal EM through the i-th light-emitting line ESLi (hereinafter referred to as a light-emitting line). The first electrode of the sixth transistor T6 may be connected to the cathode of the light-emitting element LDa through the fourth node N4, and the second electrode of the sixth transistor T6 may be connected to the first electrode of the first transistor T1a through the second node N2. The sixth transistor T6 may be referred to as a first light-emitting control transistor. When the light-emitting signal EM is supplied to the light-emitting line ESLi, the sixth transistor T6 may be turned on and electrically connect the light-emitting element LDa and the first transistor T1a to each other.

The seventh transistor T7 may be connected between the second power line VSL and the third node N3. The first electrode of the seventh transistor T7 may be connected to the second electrode of the first transistor T1a through the third node N3, and the second electrode of the seventh transistor T7 may receive the second power voltage VSS. The gate of the seventh transistor T7 may be electrically connected to the light-emitting line ESLi. The seventh transistor T7 may be referred to as a second light-emitting control transistor. When the light-emitting signal EM is supplied to the light-emitting line ESLi, the seventh transistor T7 may be turned on and electrically connect the second electrode of the first transistor T1a and the second power line VSL to each other.

In this embodiment, the sixth transistor T6 and the seventh transistor T7 are illustrated as being connected to the same light-emitting line ESLi and turned on through a same light-emitting signal EM, but this is illustrated as an example and the sixth transistor T6 and the seventh transistor T7 may be independently turned on by different signals which are distinguished from each other. Additionally, in the pixel driver PDCa according to an embodiment of the inventive concept, any one of the sixth transistor T6 and the seventh transistor T7 may be omitted.

The eighth transistor T8 may be connected between the second initialization voltage line VIL2 and the fourth node N4. That is, the eighth transistor T8 may include a gate connected to the i-th fourth scan line GBLi (hereinafter referred to as a second initialization scan line), a first electrode connected to the second initialization voltage line VIL2, and a second electrode connected to the fourth node N4. The eighth transistor T8 may be referred to as a second initialization transistor. The eighth transistor T8 may supply a second initialization voltage VINT2 to the fourth node N4 corresponding to the cathode of the light-emitting element LDa in response to a second initialization scan signal GB transmitted through the second initialization scan line GBLi. The cathode of the light-emitting element LDa may be initialized by the second initialization voltage VINT2.

In this embodiment, some of the second to eighth transistors T2, T3, T4, T5a, T6, T7, and T8 may be turned on simultaneously by a same scan signal. For example, the eighth transistor T8 and the fifth transistor T5a may be turned on simultaneously by a same scan signal. For example, the eighth transistor T8 and the fifth transistor T5a may be operated by a same compensation scan signal GC. The eighth transistor T8 and the fifth transistor T5a may be turned on/off simultaneously by a same compensation scan signal GC. In this case, the compensation scan line GCLi and the second initialization scan line GBLi may be provided as substantially a single scan line. Accordingly, the initialization of the cathode of the light-emitting element LDa and the compensation of the threshold voltage of the first transistor T1a may be performed at the same time. However, this is illustrated as an example and the inventive concept is not limited to any one embodiment.

In addition, according to the inventive concept, the initialization of the cathode of the light-emitting element LDa and the compensation of the threshold voltage of the first transistor T1a may be performed by applying a same power voltage. For example, the compensation voltage line VCL and the second initialization voltage line VIL2 may be provided as substantially a single power voltage line. In this case, the initialization operation of the cathode and the compensation operation of the driving transistor may be performed with one power voltage, and thus designing the driver may be simplified. However, this is illustrated as an example, and the inventive concept is not limited to any one embodiment.

The first capacitor C1 may be disposed between the first node N1 and the third node N3. The first capacitor C1 may store a difference voltage between the first node N1 and the third node N3. The first capacitor C1 may be referred to as a storage capacitor.

The second capacitor C2a may be disposed between the third node N3 and the second power line VSL. That is, one electrode of the second capacitor C2a may be connected to the second power line VSL that receives the second power voltage VSS, and the other electrode of the second capacitor C2a may be connected to the third node N3. The second capacitor C2a may store a charge that approximates to a voltage difference between the second power voltage VSS and the third node N3. The second capacitor C2a may be referred to as a hold capacitor. The second capacitor C2a may have a higher storage capacity than the first capacitor C1. Accordingly, the second capacitor C2a may minimize the voltage change of the third node N3 in response to the voltage change of the first node N1.

In this embodiment, the light-emitting element LDa may be connected to the pixel driver PDCa through the fourth node N4. The light-emitting element LDa may include an anode connected to the first power line VDL and a cathode opposite to the anode. In this embodiment, the light-emitting element LDa may be connected to the pixel driver PDCa through the cathode. That is, in the pixel PXija according to this inventive concept, a connection node through which the light-emitting element LDa and the pixel driver PDCa are connected to each other may be the fourth node N4, and the fourth node N4 may correspond to a connection node between the first electrode of the sixth transistor T6 and the cathode of the light-emitting element LDa. Accordingly, the potential of the fourth node N4 may substantially correspond to the potential of the cathode of the light-emitting element LDa.

Specifically, the anode of the light-emitting element LDa may be connected to the first power line VDL so that the first power voltage VDD, which is a constant voltage, is applied, and the cathode may be connected to the first transistor T1a through the sixth transistor T6. That is, in this embodiment in which the first to eighth transistors T1a, T2, T3, T4, T5a, T6, T7, and T8 are N-type transistors, the potential of the third node N3 corresponding to the source of the first transistor T1a, which is the driving transistor, may not be directly affected by the characteristics of the light-emitting element LDa. Accordingly, even though degradation of the light-emitting element LDa occurs, an effect on the gate-source voltage of the transistors constituting the pixel driver PDCa, particularly the driving transistor, may be reduced. That is, as the amount of change in driving current ILD due to degradation of the light-emitting element LDa may be reduced, the afterimage defects of the display panel DP (see FIG. 3) due to increased usage time may be reduced and the lifespan thereof may be improved.

FIGS. 4A and 4B illustrate circuits for the pixel drivers PDC and PDCa according to an embodiment of the inventive concept without limiting the inventive concept thereto. For example, the number or arrangement of the transistors and the number or arrangement of the capacitors included in the pixel driver may be changed in various ways and are not limited to any one embodiment.

FIG. 5A is a schematic plan view of a display panel DP according to an embodiment of the inventive concept. FIG. 5B is a schematic plan view of a display panel DPa according to an embodiment of the inventive concept. Each of FIGS. 5A and 5B is illustrated with some components omitted. Hereinafter, the inventive concept will be described with reference to FIGS. 5A and 5B.

Referring to FIGS. 5A and 5B, the display panel DP or DPa according to an embodiment of the inventive concept may be divided into a display region DA and a peripheral region NDA (or a non-display region). A plurality of pixels PX11 to PXnm may be disposed in the display region DA. Additionally, the display region DA may include a plurality of light-emitting portions EP.

The light-emitting portions EP may be regions in which light is emitted by the pixels PX11 to PXnm, respectively. Specifically, each of the light-emitting portions EP may correspond to a light-emitting opening OP-PDL (see FIG. 6A) which will be described later. The light-emitting opening OP-PDL may be referred to as an opening or opening portion.

The peripheral region NDA may be disposed adjacent to the display region DA. In this embodiment, the peripheral region NDA is illustrated as a shape surrounding the edge of the display region DA. However, this is illustrated as an example, and the peripheral region NDA may be disposed on one side of the display region DA or may be omitted, and the inventive concept is not limited to any one embodiment.

Referring to FIG. 5A, the display panel DP may have a shape in which a width in the first direction DR1 is greater than a length in the second direction DR2. A plurality of pixels PX11 to PXnm arranged in n rows and m columns are exemplarily illustrated as being disposed in the display region DA. In this embodiment, the display panel DP may include a plurality of scan drivers SDC1 and SDC2. The scan drivers SDC1 and SDC2 are exemplarily illustrated as including a first scan driver SDC1 and a second scan driver SDC2 disposed to be spaced apart from each other in the first direction DR1.

The first scan driver SDC1 and the second scan driver SDC2 may be built into the display panel DP. The first scan driver SDC1 and the second scan driver SDC2 may be disposed in the peripheral region NDA, but the inventive concept is not limited thereto. In an embodiment of the inventive concept, the first scan driver SDC1 and the second scan driver SDC2 may be disposed in the display region DA. That is, the first scan driver SDC1 and the second scan driver SDC2 may overlap, on a plane, at least some of the plurality of light-emitting portions EP disposed in the display region DA. As the first scan driver SDC1 and the second scan driver SDC2 are disposed in the display region DA, the area of the peripheral region NDA may be reduced compared to a typical display panel in which the scan driver is disposed in the peripheral region, and a display device with a thin bezel may be easily implemented.

The first scan driver SDC1 may be connected to some of the scan lines GL1 to GLn, and the second scan driver SDC2 may be connected to the other scan lines GL1 to GLn. For example, the first scan driver SDC1 may be connected to odd-numbered scan lines among the scan lines GL1 to GLn, and the second scan driver SDC2 may be connected to even-numbered scan lines among the scan lines GL1 to GLn.

For ease of description, FIG. 5A illustrates pads PD of the data lines DL1 to DLm. The pads PD may be defined at ends of the data lines DL1 to DLm. The data lines DL1 to DLm may be connected to the data driver DDC (see FIG. 5B) through the pads PD.

According to this inventive concept, the pads PD may be divided and arranged at positions spaced apart from each other in the peripheral region NDA with the display region DA interposed therebetween. For example, some of the pads PD may be disposed on the upper side, that is, on the side adjacent to the first scan line GL1 among the scan lines GL1 to GLn, and the other pads PD may be disposed on the lower side, that is, on the side adjacent to the last scan line GLn among the scan lines GL1 to GLn. In this embodiment, pads PD connected to odd-numbered data lines among the data lines DL1 to DLm may be disposed on the upper side, and pads PD connected to even-numbered data lines among the data lines DL1 to DLm may be disposed on the lower side.

Although not illustrated, the display panel DP may include a plurality of upper data drivers connected to the pads PD disposed on the upper side and/or a plurality of lower data drivers connected to the pads PD disposed on the lower side. However, this is an example, and the display panel DP may include one upper data driver connected to the pads PD disposed on the upper side and/or one lower data driver connected to the pads PD disposed on the lower side. The pads PD according to an embodiment of the inventive concept may be disposed on only one side of the display panel DP and connected to a single data driver, and the inventive concept is not limited to any one embodiment.

Referring to FIG. 5B, unlike the embodiment of FIG. 5A, the scan driver SDC illustrated in FIG. 5B may be provided as one part. The data driver DDC may be mounted on the display panel DPa and, for example, may be disposed in the peripheral region NDA. In an embodiment of the inventive concept, the data driver DDC may be disposed in the display region DA. In this case, some of the light-emitting portions EP disposed in the display region DA may overlap the data driver DDC on a plane.

In an embodiment of the inventive concept, the data driver DDC may be provided in the form of a separate driving chip independent of the display panel DPa and connected to the display panel DPa. However, this is an example, and the data driver DDC may be formed in the same process as the scan driver SDC to constitute the display panel DPa, and the inventive concept is not limited to any one embodiment.

In addition, as explained with reference to FIG. 5A, the scan driver SDC and/or data driver DDC of the display panel DPa in FIG. 5B may be disposed in the display region DA, and accordingly, some of the light-emitting portions EP disposed in the display region DA may overlap the scan driver SDC and/or the data driver DDC on a plane.

FIG. 6A is a cross-sectional view of a display panel DP according to an embodiment of the inventive concept.

Referring to FIGS. 4A and 6A, the display panel DP according to an embodiment of the inventive concept may include a base layer BS, a driving element layer DDL, a light-emitting element layer LDL, an encapsulation layer ECL, and a sensing layer ISL. The driving element layer DDL may include a plurality of insulating layers 10, 20, 30, 40, and 50 disposed on the base layer BS and a plurality of conductive patterns and semiconductor patterns disposed between the insulating layers 10, 20, 30, 40, and 50. The conductive patterns and the semiconductor patterns may be disposed between the insulating layers 10, 20, 30, 40, and 50 to constitute a pixel driver PDC. For ease of description, FIG. 6A illustrates a cross section of one of the regions, in which one light-emitting portion is disposed.

The base layer BS may be a member configured to provide a base surface on which the pixel driver PDC is disposed. The base layer BS may be a rigid substrate or a flexible substrate capable of being bent, folded, or rolled. The base layer BS may be a glass substrate, a metal substrate, or a polymer substrate. However, the embodiment of the inventive concept is not limited thereto, and the base layer BS may be an inorganic layer, an organic layer, or a composite material layer.

The base layer BS may have a multi-layer structure. The base layer BS may include a first polymer resin layer, a silicon oxide (SiOₓ) layer disposed on the first polymer resin layer, an amorphous silicon (a-Si) layer disposed on the silicon oxide layer, and a second polymer resin layer disposed on the amorphous silicon layer. The silicon oxide layer and the amorphous silicon layer may be referred to as a base barrier layer.

The polymer resin layer may include a polyimide-based resin. In addition, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, a “˜˜”-based resin is intended to include a functional group of “˜˜”.

Each of insulating layers, conductive layers, and semiconductor layers disposed on the base layer BS may be formed by coating, deposition, or the like. Hereafter, the insulating layer, the semiconductor layer, and the conductive layer may be selectively patterned through a plurality of photolithography processes to form a hole in the insulating layer, or a semiconductor pattern, a conductive pattern, a signal line, and the like may be formed.

The driving element layer DDL may include first to fifth insulating layers 10, 20, 30, 40, and 50 sequentially stacked on the base layer BS and a pixel driver PDC. FIG. 6A illustrates one transistor TR included in the pixel driver PDC. The transistor TR may correspond to a transistor connected to the light-emitting element LD through a connection electrode CN-P, that is, a connection transistor connected to a node (the third node N3 of FIG. 4A) corresponding to the anode of the light-emitting element LD, specifically the first transistor T1 of FIG. 4A. Although not illustrated, other transistors constituting the pixel driver PDC may have the same structure as the transistor TR (hereinafter referred to as a connection transistor) illustrated in FIG. 6A. However, this is an example, and the other transistors constituting the pixel driver PDC may have a structure different from that of the connection transistor TR, and the inventive concept is not limited to any one embodiment.

The first insulating layer 10 may be disposed on the base layer BS. The first insulating layer 10 may be an inorganic layer and/or an organic layer and have a single-layer or multi-layer structure. The first insulating layer 10 may include at least one of aluminum oxide, titanium oxide, silicon oxide, silicon nitride, silicon oxynitride, zirconium oxide, or hafnium oxide. In this embodiment, the first insulating layer 10 is illustrated as a single-layer silicon oxide layer. Insulating layers to be described later may be inorganic layers and/or organic layers and have a single-layer or multi-layer structure. The inorganic layer may include at least one of the above-mentioned materials, but is not limited thereto.

The first insulating layer 10 may cover a lower conductive layer BCL and a lower conductive line BCL-1. That is, the display panel DP may further include the lower conductive layer BCL disposed to overlap the connection transistor TR and the lower conductive line BCL-1 provided with the second power voltage VSS. The lower conductive line BCL-1 may be referred to as a second power line VSL or a power line.

The lower conductive layer BCL may block an electric potential due to a polarization phenomenon of the base layer BS from affecting the connection transistor TR. In addition, the lower conductive layer BCL may block light incident from the lower side to the connection transistor TR. At least one of an inorganic barrier layer and a buffer layer may be further disposed between the lower conductive layer BCL and the base layer BS.

The lower conductive layer BCL and the lower conductive line BCL-1 may include a reflective metal. For example, the lower conductive layer BCL and the lower conductive line BCL-1 may include titanium (Ti), molybdenum (Mo), an alloy including molybdenum, aluminum (Al), an alloy including aluminum, aluminum nitride (AlN), tungsten (W), tungsten nitride (WN), and copper (Cu).

In this embodiment, the lower conductive layer BCL may be connected to the source of the connection transistor TR (or transistor) through a first electrode pattern W1. In this case, the lower conductive layer BCL may be synchronized with the source of the transistor TR. However, this is an example, and the lower conductive layer BCL may be connected to and synchronized with the gate of the transistor TR. Alternatively, the lower conductive layer BCL may be connected to another electrode and independently receive a constant voltage or a pulse signal. Alternatively, the lower conductive layer BCL may be provided in an isolated form from another conductive pattern. The lower conductive layer BCL according to an embodiment of the inventive concept may be provided in various forms and is not limited to any one embodiment.

The connection transistor TR may be disposed on the first insulating layer 10. The connection transistor TR may include a semiconductor pattern SP and a gate electrode GE. The semiconductor pattern SP may be disposed on the first insulating layer 10. The semiconductor pattern SP may include an oxide semiconductor. For example, the oxide semiconductor may include transparent conductive oxide (TCO) such as indium tin oxide (ITO), indium zinc oxide (IZO), indium gallium zinc oxide (IGZO), zinc oxide (ZnO), or indium oxide (In₂O₃). Without being limited thereto, however, the semiconductor pattern SP may include amorphous silicon, low-temperature polycrystalline silicon, or polycrystalline silicon. The semiconductor pattern SP may include a first region SR, a second region DR, and a channel region CR divided according to the degree of conductivity. The channel region CR may be a portion that overlaps the gate electrode GE on a plane. The first region SR and the second region DR may be spaced apart from each other with the channel region CR interposed therebetween. When the semiconductor pattern SP is an oxide semiconductor, each of the first region SR and the second region DR may be a reduced region. Accordingly, the first region SR and the second region DR have a relatively higher reduced metal content than the channel region CR. Alternatively, when the semiconductor pattern SP is made of polycrystalline silicon, each of the first region SR and the second region DR may be a region doped at a high concentration.

The first region SR and the second region DR may have relatively higher conductivity than the channel region CR. The first region SR may correspond to the source electrode of the connection transistor TR, and the second region DR may correspond to the second electrode of the connection transistor TR. As illustrated in FIG. 6A, separate first and second electrode patterns W1 and W2 respectively connected to the first region SR and the second region DR may be further provided. Specifically, each of the separate first and second electrode patterns W1 and W2 may be integrally formed with one of the lines constituting the pixel driver PDC (see FIG. 4A), and the inventive concept is not limited to any one embodiment.

The second insulating layer 20 may extend to cover a plurality of pixels and the semiconductor pattern SP. The second insulating layer 20 may be an inorganic layer and/or an organic layer and have a single-layer or multi-layer structure. The second insulating layer 20 may include at least one of aluminum oxide, titanium oxide, silicon oxide, silicon nitride, silicon oxynitride, zirconium oxide, or hafnium oxide. In this embodiment, the second insulating layer 20 may be a single-layer silicon oxide layer.

The gate electrode GE may be disposed on the second insulating layer 20. The gate electrode GE may correspond to the gate of the connection transistor TR. Additionally, the gate electrode GE may be disposed above the semiconductor pattern SP. However, this is illustrated as an example, and the gate electrode GE may be disposed below the semiconductor pattern SP, and the inventive concept is not limited to any one embodiment.

The gate electrode GE may include titanium (Ti), silver (Ag), molybdenum (Mo), aluminum (Al), aluminum nitride (AlN), tungsten (W), tungsten nitride (WN), copper (Cu), or alloys thereof, but the embodiment of the inventive concept is not particularly limited thereto.

The third insulating layer 30 may be disposed on the gate electrode GE. The third insulating layer 30 may be an inorganic layer and/or an organic layer and have a single-layer or multi-layer structure. The third insulating layer 30 may include at least one of aluminum oxide, titanium oxide, silicon oxide, silicon nitride, silicon oxynitride, zirconium oxide, or hafnium oxide.

The fourth insulating layer 40 may be disposed on the third insulating layer 30. The fourth insulating layer 40 may be an inorganic layer and/or an organic layer and have a single-layer or multi-layer structure. The fourth insulating layer 40 may include at least one of aluminum oxide, titanium oxide, silicon oxide, silicon nitride, silicon oxynitride, zirconium oxide, or hafnium oxide.

A first electrode pattern W1, a second electrode pattern W2, and a connection electrode pattern W3 may be disposed on the fourth insulating layer 40. The first electrode pattern W1 may be connected to the first region SR of the connection transistor TR through a first contact hole CNT1, and the first electrode pattern W1 and the first region SR of the semiconductor pattern SP may function as the source of the connection transistor TR. The second electrode pattern W2 may be connected to the second region DR of the connection transistor TR through a second contact hole CNT2, and the second electrode pattern W2 and the second region DR of the semiconductor pattern SP may function as the drain of the connection transistor TR. The connection electrode pattern W3 may be connected to the lower conductive line BCL-1 through a third contact hole CNT3. Accordingly, the second power voltage VSS may also be provided to the connection electrode pattern W3.

The fifth insulating layer 50 may be disposed on the first electrode pattern W1, the second electrode pattern W2, and the connection electrode pattern W3. A connection electrode CN-P and a connection line CN may be disposed on the fifth insulating layer 50.

The connection electrode CN-P may electrically connect the pixel driver PDC and the light-emitting element LD to each other. That is, the connection electrode CN-P may electrically connect the connection transistor TR and the light-emitting element LD to each other. The connection electrode CN-P may be a connection node connecting the pixel driver PDC and the light-emitting element LD to each other. That is, the connection electrode CN-P may correspond to the third node N3 illustrated in FIG. 4A. This is an example, and when the connection electrode CN-P can be connected to the light-emitting element LD, the connection electrode CN-P may be defined as the connection node of various elements among the elements constituting the pixel driver PDC according to the design of the pixel driver PDC, and the inventive concept is not limited to any one embodiment.

The connection line CN may be provided to provide the second power voltage VSS to the light-emitting element LD. For example, the connection line CN may be connected to the connection electrode pattern W3. In an embodiment of the inventive concept, the connection line CN, the connection electrode pattern W3, and the lower conductive line BCL-1 may constitute a portion of the second power line VSL.

Each of the connection electrode CN-P and the connection line CN may have a three-layer structure. For example, the connection line CN may include a first layer L1, a second layer L2, and a third layer L3 sequentially stacked along the third direction DR3. The second layer L2 may include a material different from that of the first layer L1. In addition, the second layer L2 may include a material different from that of the third layer L3. The second layer L2 may be thicker than the first layer L1. Additionally, the second layer L2 may be thicker than the third layer L3. The second layer L2 may include a highly conductive material. In an embodiment of the inventive concept, the second layer L2 may include aluminum (Al).

The first layer L1 may include a material with a lower etch rate than the second layer L2. That is, the second layer L2 may be composed of materials with a high etching selectivity with respect to the first layer L1. In an embodiment of the inventive concept, the first layer L1 may include titanium (Ti), and the second layer L2 may include aluminum (Al). In this case, the side surface of the first layer L1 may extend beyond the side surface of the second layer L2.

That is, a light-emitting connection portion CE of the connection line CN may have a shape in which the side surface of the first layer L1 protrudes outward beyond the side surface of the second layer L2. That is, the light-emitting connection portion CE of the connection line CN may have a shape in which the side surface of the second layer L2 is recessed relative to the side surface of the first layer L1.

In addition, the third layer L3 may include a material with a lower etch rate than the second layer L2. That is, the third layer L3 may be composed of a material with low etching selectivity with respect to the second layer L2. In an embodiment of the inventive concept, the third layer L3 may include titanium (Ti), and the second layer L2 may include aluminum (Al). In this case, the side surface of the third layer L3 may extend beyond the side surface of the second layer L2. That is, the light-emitting connection portion CE of the connection line CN may have a shape in which the side surface of the third layer L3 protrudes outward beyond the side surface of the second layer L2. That is, the light-emitting connection portion CE of the connection line CN may have an undercut shape or an overhang structure, and a tip portion TP of the light-emitting connection portion CE may be defined by a portion of the third layer L3 that protrudes beyond the second layer L2.

The sixth insulating layer 60 may be disposed on the connection electrode CN-P and the connection line CN. The sixth insulating layer 60 may be disposed on the fifth insulating layer 50 to cover the connection electrode CN-P and the connection line CN. Each of the fifth insulating layer 50 and the sixth insulating layer 60 may be an organic layer. For example, each of the fifth insulating layer 50 and the sixth insulating layer 60 may include a general-purpose polymer such as benzocyclobutene (BCB), polyimide, hexamethyldisiloxane (HMDSO), polymethylmethacrylate (PMMA), or polystyrene (PS), a polymer derivative having a phenol-based group, an acrylic-based polymer, an imide-based polymer, an aryl ether-based polymer, an amide-based polymer, a fluorine-based polymer, a p-xylene-based polymer, a vinyl alcohol-based polymer, and blends thereof.

The sixth insulating layer 60 may be provided with an opening that exposes at least a portion of the connection line CN. The connection line CN may be electrically connected to the light-emitting element LD through a portion exposed from the sixth insulating layer 60. That is, the connection line CN may electrically connect the connection electrode pattern W3 and the light-emitting element LD to each other. In the display panel DP according to an embodiment of the inventive concept, the sixth insulating layer 60 may be omitted or provided in plurality, and the inventive concept is not limited to any one embodiment.

The light-emitting element layer LDL may be disposed on the sixth insulating layer 60. The light-emitting element layer LDL may include a pixel defining film PDL, a light-emitting element LD, a separator SPR, and spacers SPC.

The pixel defining film PDL may be an organic layer. For example, the pixel defining film PDL may include a general-purpose polymer such as benzocyclobutene (BCB), hexamethyldisiloxane (HMDSO), polyimide, polymethylmethacrylate (PMMA), or polystyrene (PS), a polymer derivative having a phenol-based group, an acrylic-based polymer, an imide-based polymer, an aryl ether-based polymer, an amide-based polymer, a fluorine-based polymer, a p-xylene-based polymer, a vinyl alcohol-based polymer, and blends thereof.

In an embodiment of the inventive concept, the pixel defining film PDL may have the property of absorbing light and have, for example, a black color. That is, the pixel defining film PDL may include a black coloring agent. The black coloring agent may include a black dye and a black pigment. The black coloring agent may include carbon black, a metal such as chromium, or an oxide thereof. The pixel defining film PDL may correspond to a light blocking pattern having the property of blocking light.

An opening OP-PDL (hereinafter referred to as a light-emitting opening), which exposes at least a portion of a first electrode EL1 that will be described later, may be defined in the pixel defining film PDL. The light-emitting opening OP-PDL may extend to the first electrode EL1. A plurality of light-emitting openings OP-PDL may be provided and disposed to respectively correspond to light-emitting elements. All the components of the light-emitting element LD may be disposed to overlap each other in the light-emitting opening OP-PDL, and the light-emitting opening OP-PDL may be a region in which light emitted by the light-emitting element LD is substantially displayed. Accordingly, the shape of the above-described light-emitting portion EP (see FIG. 5B) may substantially correspond to the shape of the light-emitting opening OP-PDL on a plane.

The sixth insulating layer 60 and the pixel defining film PDL may expose at least a portion of the tip portion TP and at least a portion of the second side surface of the second layer L2. Specifically, a first opening OP1 exposing one side of the connection line CN may be defined in the sixth insulating layer 60, and a second opening OP2 overlapping the first opening OP1 may be defined in the pixel defining film PDL. The width (e.g., as measured in the first direction DR1) of the second opening OP2 may be larger than the width of the first opening OP1. However, the embodiment of the inventive concept is not limited thereto, and as long as at least a portion of the tip portion TP and at least a portion of the second side surface of the second layer L2 can be exposed, the planar area of the second opening OP2 may be smaller than or equal to the planar area of the first opening OP1.

The light-emitting element LD may include a first electrode EL1, an intermediate layer IML, and a second electrode EL2. The first electrode EL1 may be a semi-transmissive, transmissive, or reflective electrode. According to an embodiment of the inventive concept, the first electrode EL1 may include: a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a compound thereof; and a transparent or semi-transparent electrode layer formed on the reflective layer. The transparent or semi-transparent electrode layer may include at least one selected from the group consisting of indium tin oxide (ITO), indium zinc oxide (IZO), indium gallium zinc oxide (IGZO), zinc oxide (ZnO), indium oxide (In₂O₃), and aluminum-doped zinc oxide (AZO). For example, the first electrode EL1 may include a stacked structure of ITO/Ag/ITO.

In this embodiment, the first electrode EL1 may be the anode of the light-emitting element LD. That is, the first electrode EL1 may be connected to the transistor TR through the connection electrode CN-P.

The intermediate layer IML may be disposed between the first electrode EL1 and the second electrode EL2. The intermediate layer IML may include a light-emitting layer EML and a functional layer FNL. The light-emitting element LD may include the intermediate layer IML having various structures and the inventive concept is not limited to any one embodiment. For example, the functional layer FNL may be provided as a plurality of layers, or may be provided as two or more layers spaced apart from each other with the light-emitting layer EML interposed therebetween. Alternatively, in an embodiment of the inventive concept, the functional layer FNL may be omitted.

The light-emitting layer EML may include an organic light-emitting material. In addition, the light-emitting layer EML may include an inorganic light-emitting material or may be provided as a mixed layer of an organic light-emitting material and an inorganic light-emitting material. In this embodiment, the light-emitting layer EML included in each adjacent light-emitting portion EP may include a light-emitting material that display a different color. For example, the light-emitting layer EML included in each light-emitting portion EP may provide any one of blue light, red light, and green light. Without being limited thereto, however, the light-emitting layers EML disposed in all of the light-emitting portions EP may include a light-emitting material that displays a same color. In this case, the light-emitting layer EML may provide blue light or white light.

The functional layer FNL may be disposed between the first electrode EL1 and the second electrode EL2. Specifically, the functional layer FNL may be disposed between the first electrode EL1 and the light-emitting layer EML or between the second electrode EL2 and the light-emitting layer EML. Alternatively, the functional layer FNL may be disposed not only between the first electrode EL1 and the light-emitting layer EML, but also between the second electrode EL2 and the light-emitting layer EML. FIG. 6A illustrates that the functional layer FNL includes a layer disposed between the light-emitting layer EML and the first electrode EL1 and a layer disposed between the light-emitting layer EML and the second electrode EL2 However, this is an example, and the functional layer FNL may be disposed on the light-emitting layer EML. The functional layer FNL may include a layer disposed between the light-emitting layer EML and the first electrode EL1, and/or a layer disposed between the light-emitting layer EML and the second electrode EL2, and each of these layers may be provided in plurality. The inventive concept is not limited to any one configuration of these layers.

The functional layer FNL may control the movement of charge between the first electrode EL1 and the second electrode EL2. The functional layer FNL may include a hole injection/transport material and/or an electron injection/transport material. The functional layer FNL may include at least one of an electron blocking layer, a hole transport layer, a hole injection layer, a hole blocking layer, an electron transport layer, an electron injection layer, or a charge generation layer.

The second electrode EL2 may be disposed on the intermediate layer IML. As described above, the second electrode EL2 may be connected to the connection line CN and electrically connected to the pixel driver PDC. That is, the second power voltage VSS may be provided to the second electrode EL2 through the connection line CN.

The intermediate layer IML may be disposed on the pixel defining film PDL. By the separator SPR that completely surrounds at least one light-emitting element LD, the intermediate layer IML may be separated from a region surrounding another adjacent light-emitting element LD. For example, a region defined by a closed line surrounding at least one light-emitting element LD is defined by the separator SPR. For example, the separator SPR may surround at least a portion of the light-emitting opening OP-PDL. The intermediate layer IML may be disposed within the region defined by the closed line. In this case, it is possible to prevent lateral leakage current from occurring between adjacent light-emitting elements LD.

In this specification, the “lateral leakage current” means a current flowing in a direction crossing the third direction DR3, other than a current flowing in the third direction DR3, which is the stacking direction of the light-emitting element LD, that is, the direction in which an image is displayed. The lateral leakage current may mean a current flowing in a direction parallel to a plane defined by the first direction DR1 and the second direction DR2 or in a direction similar thereto. In an embodiment of the inventive concept, the intermediate layers IML in neighboring pixels are separated from each other by the separator SPR. Accordingly, the lateral leakage current may be prevented from occurring, and as a result, color mixing due to unintended light emission from an adjacent pixel region may be prevented. Accordingly, the color representation accuracy of the display panel DP may be improved.

The second electrode EL2 may be disposed on the intermediate layer IML. The second electrode EL2 may also be disposed in part of the second opening OP2 of the pixel defining film PDL on the sixth insulating layer 60. In addition, the second electrode EL2 may also be disposed on a partial region of the connection line CN in the first opening OP1 in the sixth insulating layer 60. As illustrated in FIG. 6A, the second electrode EL2 may include a portion disposed along the upper surface of the fifth insulating layer 50 and a portion disposed along the upper surface of the connection line CN and the tip portion TP. That is, when viewed on a cross section, the second electrode EL2 may have a shape in which the second electrode EL2 is partially disconnected with respect to the tip portion TP in a region in which the light-emitting connection portion CE is defined. However, when viewed on a plane, the second electrode EL2 may be continuously formed within a closed region defined by the separator SPR.

One end of the second electrode EL2 may be disposed along and in contact with the side surface of the second layer L2. Specifically, by varying the deposition angles of the second electrode EL2 and the intermediate layer IML, the second electrode EL2 may be formed to be in contact with the side surface of the second layer L2 exposed from the intermediate layer IML by the tip portion TP. That is, the second electrode EL2 may be connected to the connection line CN without a separate patterning process for the intermediate layer IML, and accordingly, the second electrode EL2 of the light-emitting element LD may be electrically connected to the lower conductive line BCL-1 to which the second power voltage VSS is provided.

As described above, the display panel DP may include a separator SPR. The separator SPR may be disposed on the pixel defining film PDL. In an embodiment of the inventive concept, the second electrode EL2 and the intermediate layer IML may be formed by common deposition in a plurality of pixels through an open mask. In this case, the second electrode EL2 and the intermediate layer IML may be divided by the separator SPR. As described above, the separator SPR may form a closed shape for each light-emitting portion EP, and as the second electrode EL2 and the intermediate layer IML are inside the closed shape defined by the separator SPR, they may be discontinuous between adjacent light-emitting portions EP. That is, the second electrode EL2 and the intermediate layer IML may be independent for each pixel.

In an embodiment of the inventive concept, the separator SPR may have an inverted tapered cross-sectional view. That is, an angle (hereinafter referred to as a taper angle) formed by the outer side surface of the separator SPR with respect to the upper surface of the pixel defining film PDL may be an acute angle. However, this is an example, and when the separator SPR can electrically disconnect the second electrode EL2 between pixels, the taper angle may be set in various ways. In addition, the separator SPR may have the same structure as the tip portion TP and the inventive concept is not limited to any one embodiment.

In an embodiment of the inventive concept, the separator SPR may include an insulating material, particularly an organic insulating material. The separator SPR may include an inorganic insulating material, may be composed of multiple layers of an organic insulating material and an inorganic insulating material, and may include a conductive material according to an embodiment of the inventive concept. That is, as long as the intermediate layer IML and the second electrode EL2 can be separated for each pixel, the type of material of the separator SPR is not particularly limited.

A dummy layer UP may be disposed on the separator SPR. The dummy layer UP may include a first dummy layer UP1 disposed on the separator SPR and a second dummy layer UP2 disposed on the first dummy layer UP1. The first dummy layer UP1 may be formed through the same process as the intermediate layer IML, and the first dummy layer UP1 and the intermediate layer IML may include the same material as each other. The second dummy layer UP2 may be formed through the same process as the second electrode EL2, and the second dummy layer UP2 and the second electrode EL2 may include the same material as each other. That is, in a process of forming the intermediate layer IML and the second electrode EL2, the first dummy layer UP1 and the second dummy layer UP2 may be formed simultaneously with them. In another embodiment of the inventive concept, the display panel DP may not include the dummy layer UP.

In a region adjacent to the separator SPR, the second electrode EL2 may be spaced apart from the separator SPR and positioned on the pixel defining film PDL, and the second dummy layer UP2 may be separated from the second electrode EL2 and positioned on the separator SPR. FIG. 6A illustrates the second electrode EL2 and the second dummy layer UP2 are spaced apart from each other at a predetermined distance by the separator SPR, but the embodiment of the inventive concept is not limited thereto, and when the second electrode EL2 and the second dummy layer UP2 are electrically disconnected from each other, the second electrode EL2 may also be in contact with the side surface of the separator SPR. In addition, even though the second electrode EL2 and the second dummy layer UP2 are connected to each other without being distinguished from each other, when electrical resistance is high as the thickness of a portion formed along the side surface of the separator SPR is thin and the second electrode EL2 is electrically disconnected between adjacent pixels, it can be seen that the second electrode EL2 is divided by the separator SPR.

According to this inventive concept, even though there is no separate patterning process for the second electrode EL2 or the intermediate layer IML, by preventing the second electrode EL2 or the intermediate layer IML from being formed on the side surface of the separator SPR or by making it thin, the second electrode EL2 or the intermediate layer IML may discontinue between pixels. Additionally, when the second electrode EL2 or the intermediate layer IML can be electrically disconnected between adjacent pixels, the shape of the separator SPR may be modified in various ways and the inventive concept is not limited to any one shape.

A spacer SPC may be disposed on the separator SPR. The spacer SPC may be spaced apart from the pixel defining film PDL with the separator SPR interposed therebetween. Although one spacer SPC is illustrated as an example in FIG. 6A, the spacer SPC may be provided in plurality. The spacers SPC may be disposed to be spaced apart from each other on the separator SPR. Accordingly, a portion of the upper surface of the separator SPR may be exposed without being covered by the spacers SPC.

A mask may be used during a process of forming the light-emitting layer EML. For example, the mask may be a fine metal mask. Since the separator SPR is provided to separate the intermediate layer IML and the second electrode EL2 between pixels, the separators SPR occupy a predetermined proportion of the area within the display panel DP. The predetermined proportion may be about 10 percent or more. Additionally, the predetermined proportion may be about 50 percent or less.

Unlike the present invention, when the spacers SPC are not disposed, the entire upper surface of the separator SPR comes in contact with the mask. In this case, since the area of the separator SPR occupies at least a predetermined proportion of the display panel DP, a probability that the upper surface of the separator SPR will be indented by the mask may also increase. A predetermined space (e.g., a recessed portion) or a predetermined shape (e.g., a protruding portion) may be formed in a region with an indentation, and the predetermined space or the predetermined shape may have an open structure that is not completely covered by a first inorganic layer IL1 of the encapsulation layer ECL. The open structure may affect product reliability, possibly reducing product lifespan or reducing the area of the light-emitting region. According to an embodiment of the inventive concept, the spacers SPC are disposed on the separator SPR. That is, the mask may be supported by the spacers SPC. An area occupied by the spacers SPC in the display panel DP may be less than the predetermined proportion mentioned above. For example, the area occupied by the spacers SPC in the display panel DP may be less than about 3 percent. Additionally, the area occupied by the spacers SPC in the display panel DP may be 0.5 percent or more. Accordingly, since the area of the spacer SPC is less than the predetermined proportion of the display panel DP, a probability that an indentation will occur due to the mask may be reduced. In addition, since the mask is supported by the spacer SPC, a probability that the separator SPR will come in contact with the mask may be reduced. As a result, as process defects are reduced, the manufacturing yield and product reliability of the display panel DP may be improved.

The encapsulation layer ECL may be disposed on the light-emitting element layer LDL. The encapsulation layer ECL may cover the light-emitting element LD, the separator SPR, and the spacer SPC. The encapsulation layer ECL may include a first inorganic layer IL1, an organic layer OL, and a second inorganic layer IL2 sequentially stacked. Without being limited to the structure that is explicitly disclosed, however, the encapsulation layer ECL may further include a plurality of inorganic layers and organic layers. In addition, the encapsulation layer ECL may be a glass substrate.

The first and second inorganic layers ILI and IL2 may protect the light-emitting element LD from moisture and oxygen outside the display panel DP, and the organic layer OL may protect the light-emitting element LD from foreign substances such as particles remaining in a process of forming the first inorganic layer IL1. The first and second inorganic layers ILI and IL2 may include a silicon nitride layer, a silicon oxynitride layer, a silicon oxide layer, a titanium oxide layer, an aluminum oxide layer, or the like. The organic layer OL may include an acrylic-based organic layer, and the type of material is not limited to any one embodiment.

The sensing layer ISL may sense an external input. In this embodiment, the sensing layer ISL may be formed on the encapsulation layer ECL through a continuous process. In this case, the sensing layer ISL may be disposed directly on the encapsulation layer ECL. Being directly disposed may mean that no other components are disposed between the sensing layer ISL and the encapsulation layer ECL. Hence, a separate adhesive member may not be disposed between the sensing layer ISL and the encapsulation layer ECL in this embodiment. However, this is an example, and in the display panel DP according to an embodiment of the inventive concept, the sensing layer ISL may be formed separately from the display panel DP and coupled to the display panel DP using an adhesive member. The inventive concept is not limited to any one embodiment.

The sensing layer ISL may include a plurality of conductive layers and a plurality of insulating layers. The plurality of conductive layers may include a first sensing conductive layer MTL1 and a second sensing conductive layer MTL2, and the plurality of insulating layers may include first to third sensing insulating layers 71, 72, and 73. However, this is illustrated as an example, and the number of the conductive layers and the number of the insulating layers are not limited to any one embodiment.

Each of the first to third sensing insulating layers 71, 72, and 73 may have a single-layer structure or a multi-layer structure in which layers are stacked along the third direction DR3. The first to third sensing insulating layers 71, 72, and 73 may include an inorganic film. The inorganic film may include at least one of aluminum oxide, titanium oxide, silicon oxide, silicon nitride, silicon oxynitride, zirconium oxide, or hafnium oxide. The first to third sensing insulating layers 71, 72, and 73 may include an organic film. The organic film may include at least any one of an acrylic-based resin, a methacrylic-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

The first sensing conductive layer MTL1 may be disposed between the first sensing insulating layer 71 and the second sensing insulating layer 72, and the second sensing conductive layer MTL2 may be disposed between the second sensing insulating layer 72 and the third sensing insulating layer 73. A portion of the second sensing conductive layer MTL2 may be connected to the first sensing conductive layer MTL1 through a contact hole CNT formed in the second sensing insulating layer 72. Each of the first sensing conductive layer MTL1 and the second sensing conductive layer MTL2 may have a single-layer structure or a multi-layer structure in which layers are stacked along the third direction DR3.

A single-layer sensing conductive layer may include a metal layer or a transparent conductive layer. The metal layer may include molybdenum, silver, titanium, copper, aluminum, or alloys thereof. The transparent conductive layer may include a transparent conductive oxide such as indium tin oxide (ITO), indium zinc oxide (IZO), zinc oxide (ZnO), or indium zinc tin oxide (IZTO). Alternatively, the transparent conductive layer may include a conductive polymer such as PEDOT, metal nanowire, graphene, and the like.

A multi-layer sensing conductive layer may include metal layers. The metal layers may have, for example, a three-layer structure of titanium (Ti)/aluminum (Al)/titanium (Ti). Alternatively, the multi-layer sensing conductive layer may include at least one metal layer and at least one transparent conductive layer.

The first sensing conductive layer MTL1 and the second sensing conductive layer MTL2 may form a sensor that senses an external input in the sensing layer ISL. The sensor may be driven by a capacitive method and may be driven by either a mutual-capacitance method or a self-capacitance method. However, this is described as an example, and the sensor may be driven by a resistive method, an ultrasonic method, or an infrared method in addition to the capacitive method, and the inventive concept is not limited to any one embodiment.

Each of the first sensing conductive layer MTL1 and the second sensing conductive layer MTL2 may include a transparent conductive oxide and have a metal mesh shape formed of an opaque conductive material. As long as the visibility of an image displayed by the display panel DP is not reduced, the first sensing conductive layer MTL1 and the second sensing conductive layer MTL2 may include various materials and have various shapes, and the inventive concept is not limited to any one embodiment.

FIG. 6B is a cross-sectional view of a display panel DP-a according to an embodiment of the inventive concept. In describing FIG. 6B, the same reference numerals will be given to the same components as described in FIG. 6A and the descriptions thereof will be omitted.

FIG. 6B illustrates one light-emitting element LDa included in the display panel DP-a and one transistor TRa of a pixel driver PDCa electrically connected to the light-emitting element LDa. The transistor TRa may correspond to a transistor connected to the light-emitting element LDa through a connection line CNa, that is, a connection transistor connected to a node (the fourth node N4 in FIG. 4B) corresponding to the cathode of the light-emitting element LDa, specifically the sixth transistor T6 of FIG. 4B.

The connection line CNa may electrically connect the pixel driver PDCa and the light-emitting element LDa to each other. That is, the connection line CNa may electrically connect the connection transistor TRa and the light-emitting element LDa to each other. The connection line CNa may be a connection node connecting the pixel driver PDCa and the light-emitting element LDa to each other. That is, the connection line CNa may correspond to the fourth node N4 illustrated in FIG. 4B. This is an example, and as long as the connection line CNa can be connected to the light-emitting element LDa, the connection line CNa may be defined as a connection node for various elements among the elements constituting the pixel driver PDCa according to the design of the pixel driver PDCa, and the inventive concept is not limited to any one embodiment.

The connection line CNa may include a driving connection portion CD and a light-emitting connection portion CE. The driving connection portion CD may be a portion of the connection line CNa connected to the pixel driver PDCa and a portion substantially connected to the connection transistor TRa. In this embodiment, the driving connection portion CD may penetrate the fifth insulating layer 50 and be electrically connected to the second region DR of the semiconductor pattern SP through the second electrode pattern W2. The light-emitting connection portion CE may be a portion of the connection line CNa connected to the light-emitting element LDa. The light-emitting connection portion CE may be defined in a region exposed from the sixth insulating layer 60 and may be a portion to which the second electrode EL2 is connected. In this case, a tip portion TP may be defined in the light-emitting connection portion CE.

In this embodiment, the first electrode EL1 may be an anode of the light-emitting element LDa. That is, the first electrode EL1 may be connected to the first power line VDL (see FIG. 4B) and receive the first power voltage VDD (see FIG. 4B). The first electrode EL1 may be connected to the first power line VDL within the display region DA (see FIG. 5A or 5B) or may be connected to the first power line VDL in the peripheral region NDA (see FIG. 5A or 5B). In the case of the latter, the first power line VDL may be disposed in the peripheral region NDA (see FIG. 5A or 5B), and the first electrode EL1 may have a shape extending to the peripheral region NDA.

Among a plurality of conductive patterns W1, W2, CPE1, CPE2, and CPE3, a first capacitor electrode CPE1 and a second capacitor electrode CPE2 constitute the first capacitor C1. The first capacitor electrode CPE1 and the second capacitor electrode CPE2 may be spaced apart from each other with the first insulating layer 10 and the second insulating layer 20 interposed therebetween.

In an embodiment of the inventive concept, the first capacitor electrode CPE1 and the lower conductive layer BCL may have an integrated shape. In addition, the second capacitor electrode CPE2 and the gate electrode GE may have an integrated shape.

A third capacitor electrode CPE3 may be disposed on the third insulating layer 30. The third capacitor electrode CPE3 may be spaced apart from the second capacitor electrode CPE2 with the third insulating layer 30 interposed therebetween and overlap the second capacitor electrode CPE2 on a plane. The third capacitor electrode CPE3 and the second capacitor electrode CPE2 may constitute the second capacitor C2a.

The display panel DP-a may include a separator SPR. The separator SPR may be disposed on the pixel defining film PDL. In an embodiment of the inventive concept, the second electrode EL2 and the intermediate layer IML may be formed by common deposition in a plurality of pixels through an open mask. In this case, the second electrode EL2 and the intermediate layer IML may be divided by the separator SPR. As described above, the separator SPR may have a closed line shape for each light-emitting portion, and accordingly, the second electrode EL2 and the intermediate layer IML may have a divided shape for each light-emitting portion. That is, the second electrode EL2 and the intermediate layer IML may be electrically independent for each adjacent pixel.

The spacer SPC may be disposed on the separator SPR. The spacer SPC may be spaced apart from the pixel defining film PDL with the separator SPR interposed therebetween. Although one spacer SPC is illustrated as an example in FIG. 6B, a plurality of spacers SPC may be provided, even on one separator SPR. The spacers SPC may be disposed to be spaced apart from each other on the separator SPR. Accordingly, a portion of the upper surface of the separator SPR may be exposed without being covered by the spacers SPC.

Since the separator SPR is provided to separate the intermediate layer IML and the second electrode EL2, an area occupied by the separator SPR within the display panel DP-a may be a predetermined minimum proportion. According to an embodiment of the inventive concept, the spacers SPC are disposed on the separator SPR. That is, the mask may be supported by the spacers SPC. The area occupied by the spacers SPC within the display panel DP-a may be less than the predetermined proportion.

A mask may be used during a process of forming the light-emitting layer EML. The mask may be supported by the spacers SPC. Since the spacer SPC occupies a proportion less than the predetermined proportion of the display panel DP-a, a probability that an indentation will occur due to the mask may be reduced. In addition, since the mask is supported by the spacer SPC, a probability that the separator SPR will come into contact with the mask may be reduced. As a result, as process defects are reduced, the manufacturing yield and product reliability of the display panel DP-a may be improved.

FIG. 7 is a cross-sectional view of a display panel DP-1 according to an embodiment of the inventive concept. In describing FIG. 7, the same reference numerals will be given to the same components as described in FIG. 6A, and the descriptions thereof will be omitted.

Referring to FIG. 7, the display panel DP-1 may further include an intermediate connection line CN-ad disposed between the sixth insulating layer 60 and the pixel defining film PDL. The intermediate connection line CN-ad may be connected to the connection line CN through a through hole OP-60 that exposes at least a portion of the connection line CN.

In an embodiment of the inventive concept, the intermediate connection line CN-ad may be disposed on the same layer as the first electrode EL1. For example, the intermediate connection line CN-ad may have the same material and layer structure as the first electrode EL1. In addition, the intermediate connection line CN-ad may be formed through the same process as the first electrode EL1. However, this is an example and the embodiment of the inventive concept is not limited thereto. For example, the intermediate connection line CN-ad may include a material different from that of the first electrode EL1 and be formed through a process different therefrom.

A through hole OP-P may be defined in the pixel defining film PDL. The through hole OP-P and the through hole OP-60 may not be aligned to overlap each other, but the embodiment of the inventive concept is not particularly limited thereto. For example, the through hole OP-P and the through hole OP-60 may overlap each other in some embodiments. A connection electrode CNE may be disposed on the pixel defining film PDL. The connection electrode CNE may be disposed in the through hole OP-P. The connection electrode CNE may be connected to a portion of the intermediate connection line CN-ad exposed by a through hole OP-P.

The connection electrode CNE may electrically connect the lower conductive line BCL-1 and the light-emitting element LD to each other. That is, the lower conductive line BCL-1 may be electrically connected to the second electrode EL2 of the light-emitting element LD through the connection electrode pattern W3, the intermediate connection line CN-ad, and the connection electrode CNE.

The connection electrode CNE may include a first edge EG1c adjacent to the light-emitting opening OP-PDL and a second edge EG2c surrounding the first edge EG1c. The second electrode EL2 of the light-emitting element LD may be in contact with the connection electrode CNE in a region adjacent to the second edge EG2c.

The connecting electrode CNE may include transparent conductive oxide (TCO) such as indium tin oxide (ITO), indium zinc oxide (IZO), indium gallium zinc oxide (IGZO), zinc oxide (ZnO), or indium oxide (In₂O₃). However, the material constituting the connection electrode CNE is not limited to the above examples.

According to an embodiment of the inventive concept, the connection electrode CNE has a shape that surrounds at least a portion of the light-emitting portion defined in the light-emitting element LD. Accordingly, the degree of freedom of the position to which the connection electrode CNE and the light-emitting element LD are connected may be improved. Additionally, an upper surface CNE-us (see FIG. 11A) of the connection electrode CNE may be in contact with a lower surface EL2-bs (see FIG. 11A) of the second electrode EL2 of the light-emitting element LD. In this case, contact reliability between the connection electrode CNE and the second electrode EL2 may be improved. In addition, the contact reliability may be improved because the lower surface of the connection electrode CNE and the upper surface of the intermediate connection line CN-ad are in contact with each other. Accordingly, the size of the through holes OP-P for connecting the connection electrode CNE and the intermediate connection line CN-ad to each other may be reduced or minimized. Therefore, it is possible to easily increase the area or resolution of the light-emitting portion of the display panel DP-1.

FIG. 8 is a cross-sectional view of a display panel DP-2 according to an embodiment of the inventive concept. In describing FIG. 8, the same reference numerals will be given to the same components as described in FIG. 6A, and the descriptions thereof will be omitted.

Referring to FIG. 8, the through hole OP-60 exposing at least a portion of the connection line CN may be provided in the sixth insulating layer 60. The connection line CN may be connected to a connection electrode CNEa through a portion exposed from the sixth insulating layer 60 and electrically connected to the light-emitting element LD. That is, the connection line CN may electrically connect the lower conductive line BCL-1 and the light-emitting element LD to each other, along with the connection electrode CNEa. In the display panel DP-2 according to an embodiment of the inventive concept, the sixth insulating layer 60 may be omitted or may be provided in plurality, and the inventive concept is not limited to any one embodiment. When the sixth insulating layer 60 is omitted, the connection line CN may also be omitted.

The through hole OP-Pa spaced apart from the light-emitting opening OP-PDL may be defined in the pixel defining film PDL. A plurality of through holes OP-Pa may be provided and disposed to respectively correspond to the light-emitting element. The size of the through hole OP-Pa defined in the pixel defining film PDL may be larger than the size of the through hole OP-60 defined in the sixth insulating layer 60. The connection electrode CNEa may be disposed in the through hole OP-Pa and the through hole OP-60 and connected to the connection line CN.

Referring to FIGS. 7 and 8 together, since the separator SPR is provided to separate the intermediate layer IML and the second electrode EL2, the separator SPR occupies a predetermined proportion of the area within the display panel DP-1 or DP-2. According to an embodiment of the inventive concept, the spacers SPC are disposed on the separator SPR. That is, the mask may be supported by the spacers SPC. The area occupied by the spacers SPC within the display panel DP-1 or DP-2 may be less than the predetermined proportion.

A mask may be used during a process of forming the light-emitting layer EML. The mask may be supported by the spacers SPC. Since the area of the spacer SPC is less than the predetermined proportion, a probability that an indentation will occur due to the mask may be reduced. In addition, since the mask is supported by the spacer SPC, a probability that the separator SPR will come into contact with the mask may be reduced. As a result, as process defects are reduced, the manufacturing yield and product reliability of the display panel DP-1 or DP-2 may be improved.

The embodiments illustrated in FIGS. 7 and 8 have been described with respect to the connection structure of the pixel PXij previously described in FIG. 4A. For example, each of FIGS. 7 and 8 illustrates a structure in which the first electrode EL1 (referred to as an anode) of the light-emitting element LD is connected to the pixel driver PDC. However, the embodiments illustrated in FIGS. 7 and 8 may also be applied to the pixel PXija described in FIG. 4B. For example, as illustrated in FIG. 6B, the embodiments illustrated in FIGS. 7 and 8 may be modified such that the second electrode EL2 of the light-emitting element LDa is electrically connected to the pixel driver PDCa.

FIG. 9 is a cross-sectional view of a display panel DP-3 according to an embodiment of the inventive concept. In describing FIG. 9, the same reference numerals will be given to the same components as described in FIG. 6A, and redundant descriptions thereof will be omitted.

Referring to FIGS. 4A and 9, the display panel DP-3 may include a separator SPR. In order to prevent lateral leakage current from occurring between adjacent pixels, the intermediate layer IML and the second electrode EL2 may be separated by the separator SPR for each light-emitting element LD.

The display panel DP-3 may further include a connection electrode CNEb. The connection electrode CNEb may be disposed between the separator SPR and the pixel defining film PDL.

In an embodiment of the inventive concept, the connection electrode CNEb may have a shape substantially similar to that of the separator SPR on a plane. For example, the structure of the connection electrode CNEb on a plane may be similar to the structure of the separator SPR on a plane, which is illustrated in FIG. 13. Accordingly, the second electrode EL2 may be connected to the lower conductive line BCL-1 through the connection electrode CNEb exposed adjacent to the separator SPR and receive the second power voltage VSS. Accordingly, the connection electrode pattern W3, the connection line CN, and the connection electrode CNEb may be electrically connected to the lower conductive line BCL-1 to which the second power voltage VSS is transmitted.

According to an embodiment of the inventive concept, the connection electrode CNEb has a shape similar to that of the separator SPR and they are connected to each other in the display region DA (see FIG. 1A). Accordingly, the contact for connecting the lower conductive line BCL-1 and the connection electrode CNEb to each other within the display region DA may be minimized.

FIG. 10 is a cross-sectional view of a display panel DP-4 according to an embodiment of the inventive concept. In describing FIG. 10, the same reference numerals will be given to the same components as described in FIG. 6A and redundant descriptions thereof will be omitted.

Referring to FIGS. 4A and 10, the display panel DP-4 may further include a connection electrode CNEc. The connection electrode CNEc may be disposed between the separator SPR and the pixel defining film PDL. For example, the connection electrode CNEc may have a shape substantially similar to that of the separator SPR on a plane.

In an embodiment of the inventive concept, a lower conductive line BCL-la may be disposed in the peripheral region NDA. Accordingly, both a connection electrode pattern W3n connected to the lower conductive line BCL-la and a connection line CNn connected to the connection electrode pattern W3n may be disposed in the peripheral region NDA. For example, the contact for connecting the lower conductive line BCL-la and the connection electrode CNEc to each other within the display region DA may be omitted or minimized.

In an embodiment of the inventive concept, the separated second electrode EL2 may be connected to the connection electrode CNEc exposed below the separator SPR, and the connection electrode CNEc and the connection line CNn may be connected to each other by an intermediate connection line EL2n. The intermediate connection line EL2n may be formed simultaneously with the second electrode EL2 through a same process.

FIG. 11A is an enlarged cross-sectional view of a partial region of the display panel DP-1 (see FIG. 7) according to an embodiment of the inventive concept. FIG. 11B is a captured image of a partial region of the display panel DP-1 (see FIG. 7) according to an embodiment of the inventive concept. FIG. 12 is an enlarged cross-sectional view of a partial region of the display panel DP-1 (see FIG. 7) according to an embodiment of the inventive concept. FIG. 11A is an enlarged cross-sectional view of region AA′ of FIG. 7, and FIG. 12 is an enlarged cross-sectional view of region BB′ of FIG. 7.

Referring to FIGS. 7, 11A, and 11B, the separator SPR may have a double-tapered side surface. That is, with respect to a plane parallel to the upper surface of the pixel defining film PDL, a first taper angle TA1 formed by a first side surface TP1 of the separator SPR and a second taper angle TA2 formed by a second side surface TP2 thereof may be different from each other. The first taper angle TA1 and the second taper angle TA2 may be acute angles. For example, the first taper angle TA1 may be larger than the second taper angle TA2. Accordingly, the separator SPR may have an inverted tapered shape in which a lower region thereof is recessed.

In an embodiment of the inventive concept, a transition region BDA between the first side surface TP1 and the second side surface TP2 may be a curved section. That is, the transition region BDA between the first side surface TP1 and the second side surface TP2 having different taper angles may have a rounded shape with a gradually changing slope.

In an embodiment of the inventive concept, as the second side surface TP2 has a smaller taper angle than the first side surface TP1, a predetermined space may be defined between the second side surface TP2 of the separator SPR and the connection electrode CNE. The second electrode EL2 may have a shape extending toward the predetermined space.

However, the shape of the separator SPR illustrated in FIG. 11A is an example, and as long as the separator SPR can electrically disconnect the second electrode EL2 between pixels, taper angles may be set in various ways. In addition, the separator SPR may have a structure like a tip portion, and the inventive concept is not limited to any one embodiment.

In an embodiment of the inventive concept, the separator SPR may include an insulating material, particularly an organic insulating material. The separator SPR may include an inorganic insulating material, may be composed of multiple layers of organic and inorganic insulating materials, and may include a conductive material in an embodiment of the inventive concept. That is, as long as the second electrode EL2 can be electrically disconnected between pixels, the type of material of the separator SPR is not particularly limited.

The functional layer FNL may include a first intermediate functional layer FNLa disposed between the first electrode EL1 and the light-emitting layer EML and a second intermediate functional layer FNLb disposed between the second electrode EL2 and the light-emitting layer EML. In an embodiment of the inventive concept, one of the first intermediate functional layer FNLa and the second intermediate functional layer FNLb may be omitted.

The first dummy layer UP1 may include a (1-1)-th dummy layer UP1a and a (1-2)-th dummy layer UP1b. The (1-1)-th dummy layer UP1a may be formed through the same process as the first intermediate functional layer FNLa and include the same material as the first intermediate functional layer FNLa. The (1-2)-th dummy layer UP1b may be formed through the same process as the second intermediate functional layer FNLb and include the same material as the second intermediate functional layer FNLb.

Referring to FIG. 12, the separator SPR may include a first portion SP1 including the first side surface TP1 and a second portion SP2 including the second side surface TP2. The first portion SP1 may be disposed on the second portion SP2, and the first portion SP1 may be spaced apart from the pixel defining film PDL with the second portion SP2 interposed therebetween. A first width WT1 of the first portion SP1 may be greater than a second width WT2 of the second portion SP2. The minimum width of the first width WT1 may be greater than or equal to the maximum width of the second width WT2. Additionally, the minimum width of the second portion SP2 may be smaller than the minimum width of the first portion SP1.

The spacer SPC may be disposed on an upper surface SPRu of the separator SPR. The first portion SP1 is interposed between the spacer SPC and the second portion SP2. The spacer SPC may be disposed like an island on the separator SPR and have a width smaller than that of the upper surface SPRu of the separator SPR. Accordingly, a portion of the upper surface SPRu of the separator SPR may be exposed and covered by the first dummy layer UP1.

A mask may be used during the process of forming the light-emitting layer EML. The mask may be supported by spacers SPC. The area of the spacer SPC may be smaller than the area of the upper surface SPRu of the separator SPR in plan view. Accordingly, a probability that the spacer SPC will be indented by the mask may be reduced. In addition, since the mask is supported by the spacer SPC, a probability that the separator SPR will come into contact with the mask may be reduced. As a result, process defects are reduced, and manufacturing yield and product reliability of the display panel DP-1 may be improved.

Although FIG. 12 exemplarily illustrates that the spacer SPC has a rectangular shape on a cross section, the inventive concept is not limited to any particular shape of the spacer SPC. For example, the spacer SPC may have a trapezoidal cross section. In an embodiment of the inventive concept, the thickness of the spacer SPC may be less than or equal to the thickness of the separator SPR. However, this is not a limitation of the inventive concept.

FIG. 13 is an enlarged plan view of a partial region of the display panel DP (see FIG. 1A) according to an embodiment of the inventive concept.

FIG. 13 illustrates two rows and two columns of light-emitting units UT11, UT12, UT21, and UT22. Referring to FIG. 13, first row Rk light-emitting portions include light-emitting portions constituting a first row, first column light-emitting unit UT11 and a first row, second column light-emitting unit UT12, and second row Rk+1 light-emitting portions include light-emitting portions constituting a second row, first column light-emitting unit UT21 and a second row, second column light-emitting unit UT22.

Each of light-emitting portions EP1, EP2, and EP3 may correspond to a light-emitting opening OP-PDL (see FIG. 6A). That is, each of the light-emitting portions EP1, EP2, and EP3 may be a region in which light is emitted by the above-described light-emitting element. The light-emitting portions EP1, EP2, and EP3 may correspond to a unit constituting an image displayed on the display panel DP (see FIG. 1A). More specifically, each of the light-emitting portions EP1, EP2, and EP3 may correspond to a region defined by the light-emitting opening OP-PDL, particularly a region defined by the lower surface of the light-emitting opening OP-PDL.

The light-emitting portions EP1, EP2, and EP3 may include a first light-emitting portion EP1, a second light-emitting portion EP2, and a third light-emitting portion EP3. The first light-emitting portion EP1, the second light-emitting portion EP2, and the third light-emitting portion EP3 may emit lights of different colors. For example, the first light-emitting portion EP1 may emit red light, the second light-emitting portion EP2 may emit green light, and the third light-emitting portion EP3 may emit blue light, but the combination of colors is not limited thereto. Additionally, at least two of the first to third light-emitting portions EP1, EP2, and EP3 may emit light of a same color. For example, the first to third light-emitting portions EP1, EP2, and EP3 may all emit blue light, or all of them may emit white light.

Among the first to third light-emitting portions EP1, EP2, and EP3, the third light-emitting portion EP3, which displays light emitted by the third light-emitting element, may include two sub-light-emitting portions EP31 and EP32 spaced apart from each other in the second direction DR2. However, this is an example, and like the first and second light-emitting portions EP1 and EP2, the third light-emitting portion EP3 may be provided as a single pattern having an integrated shape, and at least any one of the first and second light-emitting portions EP1 and EP2 may include sub-light-emitting portions spaced apart from each other, and the inventive concept is not limited to any one embodiment.

In an embodiment of the inventive concept, the shapes of the light-emitting portions constituting the first row, first column light-emitting unit UT11 and the light-emitting portions constituting the second row, second column light-emitting unit UT22 may be substantially the same as each other. Additionally, the shapes of the light-emitting portions constituting the first row, second column light-emitting units UT12 and the light-emitting portions constituting the second row, first column light-emitting units UT21 may be substantially the same as each other. The shape of the light-emitting portions constituting the first row, first column light-emitting unit UT11 may be different from the shape of the light-emitting portions constituting the first row, second column light-emitting unit UT12. For example, some of the first row Rk light-emitting portions and some of the second row Rk+1 light-emitting portions may have shapes symmetrical to each other with respect to an imaginary line extending between the first row Rk and the second row Rk+1.

The two rows and two columns of the light-emitting units UT11, UT12, UT21, and UT22 may be repeatedly arranged along the first direction DR1 and the second direction DR2 within the display panel DP (see FIG. 1A). That is, the two rows and two columns of the light-emitting units UT11, UT12, UT21, and UT22 may be defined as one repeating unit group, and another two rows and two columns of the light-emitting units adjacent to the two rows and two columns of the light-emitting units UT11, UT12, UT21, and UT22 may have the same arrangement as the two rows and two columns of the light-emitting units UT11, UT12, UT21, and UT22. Accordingly, the two rows and two columns of the light-emitting units UT11, UT12, UT21, and UT22 may be defined as one group. That is, the plurality of light-emitting portions may be divided into a plurality of groups having a same arrangement. A partial region of the display panel DP (see FIG. 1A) illustrated in FIG. 14 may correspond to a unit region including one group, that is, the two rows and two columns of the light-emitting units UT11, UT12, UT21, and UT22.

The separator SPR may divide the display panel DP (see FIG. 1A) into regions in which the light-emitting elements, for example, the first to third light-emitting portions EP1, EP2, and EP3 are disposed. The first to third light-emitting portions EP1, EP2, and EP3 may each be disposed in its own region defined by the separator SPR. The separator SPR may include a plurality of first lines SL1 extending in the first direction DR1 and a plurality of second lines SL2 extending in the second direction DR2 crossing the first direction DR1.

FIG. 14 is an enlarged plan view of a partial region of the display panel according to an embodiment of the inventive concept.

Referring to FIGS. 12, 13, and 14, the spacers SPC may be disposed to be spaced apart from each other in the first direction DR1. Accordingly, the upper surface SPRu of the separator SPR may not be completely covered by the spacers SPC.

In an embodiment of the inventive concept, the spacers SPC may be arranged along the boundaries between the first row, first column light-emitting unit UT11 and the second row, first column light-emitting unit UT21 and between the first row, second column light-emitting unit UT12 and the second row, second column light-emitting unit UT22.

A first proportion of an area occupied by the separator SPR out of an area of one unit region may be greater than a second proportion of an area occupied by the spacers SPC out of the area of the one unit region. For example, when the first proportion is about 10 percent to 50 percent, the second proportion may be 0.5 percent to about 3 percent.

According to an embodiment of the inventive concept, the spacers SPC are disposed on the separator SPR. Accordingly, the mask which is used during a manufacturing process of the display panel may be supported by the spacers SPC. Accordingly, a probability that the separator SPR will come into contact with the mask may be reduced, and therefore, a probability that the upper surface SPRu of the separator SPR will be dented may also be reduced. As a result, as process defects are reduced, and manufacturing yield and product reliability of the display panel may be improved.

FIG. 15 is an enlarged plan view of a partial region of the display panel according to an embodiment of the inventive concept.

Referring to FIG. 15, spacers SPCa may be disposed to be spaced apart from each other in the first direction DR1 and the second direction DR2.

The spacers SPCa may be disposed to correspond one-to-one with cross-intersection regions CR1 in which a first line SL1 extending in the first direction DR1 and a second line SL2 extending generally in the second direction DR2 cross each other. In addition, the spacers SPCa may be disposed to correspond one-to-one with T-shaped intersection regions CR2 in which one of the first line SL1 and the second line SL2, which extends in a predetermined direction, meet the other.

FIG. 16 is an enlarged plan view of a partial region of the display panel according to an embodiment of the inventive concept.

Referring to FIG. 16, spacers SPCb may be disposed to be spaced apart from each other in the first direction DR1 and the second direction DR2.

The spacers SPCb may be disposed to correspond one-to-one with at least some of the cross-intersection regions CR1 in which the first line SL1 and the second line SL2 cross each other and extend. In addition, the spacers SPCb may be disposed to correspond one-to-one with at least some of the T-shaped intersection regions CR2 in which one of the first line SL1 and the second line SL2, which extends in a predetermined direction, is in contact with the other.

The arrangement density of the spacers SPCb illustrated in FIG. 16 may be lower than the arrangement density of the spacers SPCa illustrated in FIG. 15. According to an embodiment of the inventive concept, the arrangement density of the spacers SPCb may be adjusted in various ways.

FIG. 17 is an enlarged plan view of a partial region of the display panel according to an embodiment of the inventive concept.

Referring to FIG. 17, spacers SPCc may be disposed on the first lines SL1 of the separator SPR extending along the first direction DR1. For example, the spacers SPCc may not be disposed in the cross-intersection region CR1 and the T-shaped intersection region CR2.

In an embodiment of the inventive concept, the spacers SPCc may be disposed on the second lines SL2 of the separator SPR extending along the second direction DR2 and may not be disposed on the first lines SL1 thereof.

Alternatively, in an embodiment of the inventive concept, the spacers SPCc may be disposed on the first lines SL1 and the second lines SL2 and may not be disposed in the cross-intersection regions CR1 and the T-shaped intersection regions CR2.

In addition, in an embodiment of the inventive concept, the spacers SPCc may be disposed on at least one of the first lines SL1 or the second lines SL2 and may be disposed on at least one of the cross-intersection regions CR1 or the T-shaped intersection regions CR2.

FIG. 18 is an enlarged plan view of a partial region of the display panel according to an embodiment of the inventive concept.

Referring to FIG. 18, spacers SPCd may be disposed on the cross-intersection regions CR1 and the first lines SL1 of the separator SPR extending along the first direction DR1.

In an embodiment of the inventive concept, one display panel DP (see FIG. 1A) may have an arrangement structure of the spacers described with reference to FIGS. 14 to 18. For example, a structure like the embodiment in FIG. 15, which has a relatively high arrangement density of the spacers, may be applied to the central portion of the display panel DP in which a probability that the mask will sag is high, and a structure like that of FIG. 14, 16, 17, or 18, which has a relatively low arrangement density of the spacers, may be applied to the edge portion of the display panel DP.

FIG. 19 is an enlarged plan view of a partial region of the display panel according to an embodiment of the inventive concept.

Referring to FIG. 19, spacers with various shapes are illustrated as an example. The shapes of the spacers described below refer to their shapes when viewed on a plane.

A first-type spacer SPCt1 may have a square shape, and a second-type spacer SPCt2 may have a rectangular shape. A third-type spacer SPCt3 may have a cross shape. A fourth-type spacer SPCt4 may have a right angle clamp shape. A fifth-type spacer SPCt5 may have a diamond shape. A sixth-type spacer SPCt6 may have a triangular shape. A seventh-type spacer SPCt7 may have a T shape. An eighth-type spacer SPCt8 may have a rectangular shape. In addition to the illustrated embodiments, the spacer may have various shapes such as a circular, oval, or an irregular shape on a plane.

The maximum width of the second-type spacer SPCt2 may be less than or equal to twice the maximum width of the first line SL1 or the second line SL2, and the maximum width of the eighth-type spacer SPCt8 may be greater than or equal to the maximum width of the first line SL1 or the second line SL2. FIG. 19 illustrates that a width LT1 of the eighth-type spacer SPCt8 in the first direction DR1 is greater than a length LT2 thereof in the second direction DR2 and that the eighth-type spacer SPCt8 is disposed on the first line SL1.

The third-type spacer SPCt3 may be disposed in the cross-intersection region CR1 in which the first line SL1 and the second line SL2 cross each other and extend. The fourth-type spacer SPCt4 may be disposed in a portion in which one end of the first line SL1 and one end of the second line SL2 are in contact with each other. The seventh-type spacer SPCt7 may be disposed in the T-shaped intersection region CR2 in which one among the first line SL1 and the second line SL2, which extends in a predetermined direction, is in contact with the other.

FIGS. 14 to 18 exemplarily illustrate that the shapes of all the spacers are those of the first-type spacers SPCt1, but the shapes thereof are not particularly limited thereto. For example, in FIGS. 14 to 18, the shape of each spacer may be replaced with any one of the first- to eighth-type spacers SPCt1 to SPCt8. That is, spacers in a single display panel DP (see FIG. 1A) may have a matching shape or different shapes.

The display panel according to an embodiment of the inventive concept may include a plurality of light-emitting elements, a separator, and a spacer disposed on the separator. Each of the plurality of light-emitting elements may include a first electrode, an intermediate layer, and a second electrode, and the intermediate layers and the second electrodes of the plurality of light-emitting elements may be separated from each other by the separator. Accordingly, as the intermediate layers are separated from each other, lateral leakage current may be prevented from occurring, and as a result, color mixing due to unintended light emission from adjacent pixel regions may be prevented. Accordingly, the color representation accuracy of the display panel may be improved.

Additionally, the second electrode may be the cathode of the light-emitting element. As the second electrodes are separated from each other, the cathode of the light-emitting element may be connected to the pixel driver. Therefore, even though the light-emitting element deteriorates, changes in the gate-source voltage of the driving transistor in the pixel driver may be prevented. Accordingly, the afterimage defects of the display panel due to increased usage time may be reduced and the lifespan of the display panel may be lengthened.

In addition, a spacer that occupies a relatively small area is disposed on the separator. That is, even though the area occupied by the separator provided to separate the intermediate layer and the second electrode between pixels in the display panel increases, defects due to the indentation of the separator by the mask during a manufacturing process of the display panel may be reduced or eliminated. As a result, as process defects are reduced, the manufacturing yield and product reliability of the display panel may be improved.

Although the above has been described with reference to example embodiments of the inventive concept, those skilled in the art or those of ordinary skill in the art will understand that various modifications and changes can be made to the inventive concept within the scope that does not depart from the spirit and technical field of the inventive concept described in the claims to be described later. Accordingly, the technical scope of the inventive concept should not be limited to the content described in the detailed description of the specification, but should be determined by the claims presented hereinafter.

What is claimed is:

1. A display panel comprising:
a driving element layer comprising a pixel driver;
a light-emitting element disposed on the driving element layer and comprising a first electrode, an intermediate layer disposed on the first electrode, and a second electrode disposed on the intermediate layer;
a pixel defining film disposed on the driving element layer and having an opening that exposes at least a portion of the first electrode;
a separator disposed on the pixel defining film and surrounding at least a portion of the opening, wherein the separator comprises:
a first portion including a first side surface having a first taper angle; and
a second portion including a second side surface having a second taper angle different from the first taper angle,
wherein:
a first width of the first portion is greater than a second width of the second portion; and
a plurality of spacers disposed on the separator and spaced apart from each other;
wherein the first portion is between the plurality of spacers and the second portion.

2. The display panel of claim 1, wherein:
the separator comprises a line extending along a first direction; and
the plurality of spacers are spaced apart from each other along the first direction.

3. The display panel of claim 1, wherein, when viewed on a plane, the separator comprises:
a plurality of first lines extending in a first direction; and
a plurality of second lines extending in a second direction that crosses the first direction.

4. The display panel of claim 3, wherein the separator further comprises a plurality of cross-intersection regions where the plurality of first lines and the plurality of second lines intersect.

5. The display panel of claim 4, wherein the plurality of spacers are disposed to correspond one-to-one with at least some of the plurality of cross-intersection regions.

6. The display panel of claim 4, wherein the plurality of spacers comprise a spacer having a cross shape, and
wherein the spacer is disposed in one of the plurality of cross-intersection regions.

7. The display panel of claim 3, wherein the separator further comprises a plurality of T-shaped intersection regions in which the plurality of first lines and the plurality of second lines meet.

8. The display panel of claim 7, wherein the plurality of spacers comprise a spacer having a T shape, and
wherein the spacer is disposed in one of the plurality of T-shaped intersection regions.

9. The display panel of claim 3, wherein the plurality of spacers comprise a spacer having a shape in which a width in the first direction is greater than a length in the second direction, and
wherein the spacer overlaps one of the plurality of first lines.

10. The display panel of claim 1, wherein the plurality of spacers comprises a spacer having at least one of a circular, tetragonal, triangular, and an irregular shape.

11. The display panel of claim 1, wherein the light-emitting element is provided as a plurality of light-emitting elements,
wherein a plurality of light-emitting portions are defined in the plurality of light-emitting elements,
the plurality of light-emitting portions are divided into a plurality of groups having a same arrangement; and
a first proportion of an area occupied by the separator out of an area of a unit region is greater than a second proportion of an area occupied by the plurality of spacers out of the area of the unit region, wherein the unit region includes one of the plurality of groups.

12. The display panel of claim 11, wherein a plurality of intermediate layers and a plurality of second electrodes included in the plurality of light-emitting elements are separated from each other by the separator.

13. The display panel of claim 1, wherein:
the driving element layer further comprises a power line that receives a power voltage;
the first electrode is electrically connected to the power line; and
the second electrode is connected to the pixel driver.

14. The display panel of claim 1, wherein:
the driving element layer further comprises a power line that receives a power voltage;
the first electrode is connected to the pixel driver; and
the second electrode is electrically connected to the power line.

15. A display panel comprising:
a driving element layer comprising a pixel driver;
a plurality of light-emitting elements disposed on the driving element layer;
a pixel defining film disposed on the driving element layer and having a plurality of openings aligned with the plurality of light-emitting elements;
a separator disposed on the pixel defining film and dividing the display panel into regions in which the plurality of light-emitting elements are disposed; and
a plurality of spacers disposed on the separator and spaced apart from each other,
wherein:
a portion of an upper surface of the separator is exposed between the plurality of spacers.

16. The display panel of claim 15, wherein the plurality of light-emitting elements comprise:
a plurality of first electrodes;
a plurality of intermediate layers disposed on the plurality of first electrodes; and
a plurality of second electrodes disposed on the plurality of intermediate layers,
wherein the plurality of intermediate layers are separated from each other by the separator, and the plurality of second electrodes are separated from each other by the separator,
wherein the separator comprises:
a first portion including a first side surface having a first taper angle and a second portion including a second side surface having a second taper angle different from the first taper angle,
wherein:
a first width of the first portion is greater than a second width of the second portion; and
the plurality of spacers are disposed on the first portion that is between the plurality of spacers and the second portion.

17. The display panel of claim 15, wherein:
when viewed on a plane, the separator comprises a plurality of first lines extending in a first direction and a plurality of second lines extending in a second direction that crosses the first direction; and
the plurality of spacers are spaced apart from each other in at least one of the first direction and the second direction.

18. An electronic device comprising a display panel,
wherein the display panel comprises:
a driving element layer comprising a pixel driver and a power line that receives a power voltage;
a light-emitting element disposed on the driving element layer and comprising a first electrode, an intermediate layer disposed on the first electrode, and a second electrode disposed on the intermediate layer;
a pixel defining film disposed on the driving element layer and having an opening that exposes at least a portion of the first electrode;
a separator disposed on the pixel defining film and surrounding at least a portion of the opening; and
a plurality of spacers disposed on the separator and spaced apart from each other,
wherein a portion of an upper surface of the separator is exposed between the plurality of spacers.

19. The electronic device of claim 18, wherein the separator comprises:
a first portion including a first side surface having a first taper angle; and
a second portion including a second side surface having a second taper angle different from the first taper angle,
wherein:
a first width of the first portion is greater than a second width of the second portion; and
the plurality of spacers are spaced apart from the second portion with the first portion interposed therebetween.

20. The electronic device of claim 18, wherein the display panel further comprises a connection electrode disposed between the pixel defining film and the separator, and
wherein the second electrode is connected to the connection electrode adjacent to a side surface of the separator.
